(19) United States
(12) Patent Application Publication
(10) Pub. No.: US 2024/0170424 A1
(43) Pub. Date: May 23, 2024

(54) THREE-DIMENSIONAL MEMORY DEVICES AND FABRICATING METHODS THEREOF

(71) Applicant: YANGTZE MEMORY TECHNOLOGIES CO., LTD., Wuhan (CN)

(72) Inventors: Kun Zhang, Wuhan (CN); Wenxi Zhou, Wuhan (CN); Jing Gao, Wuhan (CN); Zhiliang Xia, Wuhan (CN); Zongliang Huo, Wuhan (CN)

(21) Appl. No.: 18/078,898

(22) Filed: Dec. 9, 2022

Related U.S. Application Data
(63) Continuation of application No. PCT/CN2022/133741, filed on Nov. 23, 2022.

(51) Int. Cl. H01L 23/00; H01L 25/00; H01L 25/065; H01L 25/18

(52) U.S. Cl. CPC H01L 24/08; H01L 24/80; H01L 25/0657; H01L 25/18; H01L 25/50; H01L 2224/08145; H01L 2224/80895; H01L 2224/80896; H01L 2924/1431; H01L 2924/14511

(57) ABSTRACT

Three-dimensional (3D) memory devices and fabricating methods thereof are disclosed. In certain aspects, a method for forming a 3D memory device can comprise forming a first semiconductor structure, comprising forming a stack structure on a first substrate, and forming a gate line slit structure including a filling structure penetrating the stack structure and extending into the first substrate. The method can further comprise forming a second semiconductor structure including a periphery circuit on a second substrate, and bonding the second semiconductor structure to the first semiconductor structure. The method can further comprise removing a portion of the first substrate and a portion of the gate line slit structure extended into the first substrate, and forming a supplemental semiconductor layer on a remaining portion of the first substrate.

### CROSS-REFERENCE TO RELATED APPLICATIONS

This application is a continuation of Internal Application No. PCT/CN2022/133741, filed Nov. 23, 2022, entitled “THREE-DIMENSIONAL MEMORY DEVICES AND FABRICATING METHODS THEREOF,” which is incorporated herein by reference in its entirety.

### TECHNICAL FIELD

The present disclosure generally relates to the field of semiconductor technology, and more particularly, to a three-dimensional (3D) memory device and a fabricating method thereof.

### BACKGROUND

With continuous rising and development of artificial intelligence (AI), big data, Internet of Things, mobile devices and communications, and cloud storage, etc., the demand for memory capacity are growing in an exponential way. Compared with other non-volatile memories, NAND memory has many advantages, such as high integration, low power consumption, fast programming/erasing speed, good reliability, low cost, etc., and thus has gradually become the mainstream semiconductor memory in the industry.

Planar NAND memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) NAND memory architecture can address the density limitation in planar memory cells. The 3D memory architecture includes a memory array and periphery devices for controlling signals to and from the memory array.

### SUMMARY

In one aspect of the present disclosure, a method for forming a three-dimensional (3D) memory device is disclosed. The method comprises: forming a first semiconductor structure, comprising: forming a stack structure on a first substrate, and forming a gate line slit structure including a filling structure penetrating the stack structure and extending into the first substrate; forming a second semiconductor structure including a periphery circuit on a second substrate; bonding the second semiconductor structure to the first semiconductor structure; removing a portion of the first substrate and a portion of the gate line slit structure extended into the first substrate; and forming a supplemental semiconductor layer on a remaining portion of the first substrate.

In some implementations, forming the first semiconductor structure further comprises: forming the first substrate including a sacrificial substrate, a first stop layer, an initial semiconductor layer, a second stop layer, and a barrier layer stacked in a vertical direction.

In some implementations, forming the first semiconductor structure further comprises: forming a dielectric stack structure including a plurality of dielectric layer pairs stacked on the first substrate, each dielectric layer pair including a sacrificial layer and a dielectric layer different from the sacrificial layer; and forming a plurality of channel structures penetrating the dielectric stack structure, each channel structure including a functional layer and a semiconductor channel.

In some implementations, forming the first semiconductor structure further comprises: forming a slit penetrating the dielectric stack structure and extending into the first substrate; and converting the dielectric stack structure into a memory stack.

In some implementations, converting the dielectric stack structure into the memory stack comprises: removing the plurality of stack sacrificial layers in the dielectric stack structure through the slit to form a plurality of horizontal trenches; forming a high-k dielectric layer to cover exposed surfaces of the plurality of horizontal trenches and on sidewalls and on a bottom of the slit; and forming a gate structure in each horizontal trench.

In some implementations, forming the gate line slit structure comprises forming at least one gate line spacer layer on the high-k dielectric layer; and forming the filling structure to fill the slit.

In some implementations, the method further comprises: before forming the high-k dielectric layer, performing an oxidization process to oxidize a portion of the barrier layer exposed by the slit.

In some implementations, removing the portion of the first substrate and the portion of the gate line slit structure comprises: removing the sacrificial substrate and stopping at the first stop layer; removing the first stop layer and the initial semiconductor layer and stopping at the second stop layer to expose portions of the channel structures and portions of the high-k dielectric layer of the gate line slit structure; removing a portion of the functional layer of each channel structure to expose the semiconductor channel; and doping a portion of the semiconductor channel of each channel structure.

In some implementations, removing the portion of the functional layer of each channel structure comprises: removing portions of a blocking layer, a storage layer, and a tunneling layer of each channel structure that extend beyond the barrier layer; and simultaneously removing the second stop layer.

In some implementations, the method further comprises removing portions of the high-k dielectric layer and portions of the at least one gate line spacer layer that extend beyond the barrier layer to expose a portion of the filling structure extended beyond the barrier layer.

In some implementations, forming the supplemental semiconductor layer comprises forming the supplemental semiconductor layer on the barrier layer to electrically connect with the doped portion of the semiconductor channel of each channel structure; performing a local thermal to active the supplemental semiconductor layer; and performing a chemical mechanical polishing process to planarize a top surface of the supplemental semiconductor layer.

In some implementations, the method further comprises forming a connecting layer on the supplemental semiconductor layer to electrically connect between portions of the supplemental semiconductor layer that are separated by the gate line slit structure.

In some implementations, the method further comprises forming a pad layer on the supplemental semiconductor layer.

In some implementations, forming the pad layer comprises forming a pad dielectric layer on the supplemental semiconductor layer; forming a plurality of pad structures embedded in the pad dielectric layer; forming a wiring layer on the pad dielectric layer to connect with the plurality of pad structures; and forming a protection layer to cover the wiring layer.

In some implementations, bonding the second semiconductor structure to the first semiconductor structure comprises: hybrid bonding the second semiconductor structure to the first semiconductor structure in a face-to-face manner.

Another aspect of the present disclosure provides a three-dimensional (3D) memory device, comprising: a first semiconductor structure comprising: a stack structure comprising alternately arranged gate structures and dielectric layers on a semiconductor layer, and a gate line slit structure extending through the stack structure, comprising a filling structure sandwiched by gate line spacer layers; and a second semiconductor structure comprising a periphery circuit; wherein the second semiconductor structure coupled to the first semiconductor structure.

In some implementations, the first semiconductor structure further comprises: a connecting layer on the semiconductor layer to electrically connect portions of the semiconductor layer that are separated by the gate line slit structure.

In some implementations, the filling structure is extended into and in direct contact with the semiconductor layer.

In some implementations, the first semiconductor structure further comprises: a barrier layer between the stack structure and the semiconductor layer; and a plurality of channel structures extending through the stack structure and the barrier layer, each channel structure including a functional layer and a semiconductor channel.

In some implementations, the first semiconductor structure further comprises: a staircase structure in the stack structure; and a plurality of dummy channel structures penetrating the staircase structure.

In some implementations, the first semiconductor structure further comprises: a plurality of word line contacts each in contact with a corresponding gate structure; a plurality of channel structure contacts each in contact with the semiconductor channel of a corresponding channel structure; and a plurality of first interconnect contacts each connected with a corresponding one of the plurality of word line contacts or the plurality of channel structure contacts.

In some implementations, the functional layer of each channel structure comprises a blocking layer, a storage layer, and a tunneling layer; and the semiconductor channel comprises: an undoped semiconductor channel region in contact with a corresponding channel structure contact, and a doped semiconductor channel region penetrating the barrier layer and in contact with the semiconductor layer.

In some implementations, the second semiconductor structure and the first semiconductor structure are hybrid bonded together in a face-to-face manner, such that the first interconnect contacts of the first semiconductor structure are respectively connected with a plurality of second interconnect contacts of the second semiconductor structure at the bonding interface.

In some implementations, the device further comprises a pad layer on the semiconductor layer, the pad layer comprising: a dielectric layer attached to the semiconductor layer; a plurality of pad structures embedded in the pad dielectric layer; a wiring layer attached to the pad dielectric layer to connect with the plurality of pad structures; and a protection layer covering the wiring layer.

In some implementations, the device further comprises a pad layer on the semiconductor layer, the pad layer comprising: a dielectric layer attached to the connecting layer; a plurality of pad structures embedded in the pad dielectric layer; a wiring layer attached to the pad dielectric layer to connect with the plurality of pad structures; and a protection layer covering the wiring layer.

In some implementations, the first semiconductor structure further comprises a high-k dielectric layer located between adjacent dielectric layer and gate structure along a lateral direction, and between the stack structure and the gate line slit structure along a vertical direction.

In some implementations, the first semiconductor structure further comprises an oxide structure between the high-k dielectric layer and the barrier layer.

In some implementations, the high-k dielectric layer is in direct contact with the barrier layer.

Another aspect of the present disclosure provides a memory system, comprising: a memory device configured to store data, and comprising: a first semiconductor structure comprising: a stack structure comprising an array of memory cells, and a gate line slit structure extending through the stack structure, comprising a filling structure sandwiched by gate line spacer layers; and a second semiconductor structure comprising a periphery circuit, wherein the second semiconductor structure coupled to the first semiconductor structure; and a memory controller coupled to the memory device and configured to control the array of memory cells through the periphery circuit.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic diagram of a cross-section of an exemplary 3D memory device, according to some aspects of the present disclosure.

FIG. 2 illustrates a schematic circuit diagram of an exemplary memory device, according to some aspects of the present disclosure.

FIG. 3 illustrates a schematic circuit diagram of an exemplary memory device, according to some aspects of the present disclosure.

FIGS. 4A-4B illustrate schematic structural diagrams of exemplary 3D memory devices in a cross-sectional side view, according to various implementations of the present disclosure.

FIGS. 5A-5B illustrate schematic structural diagrams of exemplary 3D memory devices in a cross-sectional side view, according to various implementations of the present disclosure.

FIG. 6 illustrates a block diagram of an exemplary system having a 3D memory device, according to some aspects of the present disclosure.

FIG. 7A illustrates a diagram of an exemplary memory card having a 3D memory device, according to some aspects of the present disclosure.

FIG. 7B illustrates a diagram of an exemplary solid-state drive (SSD) having a 3D memory device, according to some aspects of the present disclosure.

FIGS. 8 and 8 illustrate flow diagrams of an exemplary method for forming a 3D memory device, according to s some aspects of the present disclosure.

FIGS. 9A-9G illustrate schematic cross-sectional views of an exemplary 3D memory device at certain fabricating stages of the method shown in FIG. 8, according to some aspects of the present disclosure.

FIGS. 10A-10B illustrate schematic cross-sectional views of an exemplary 3D memory device at certain fabricating stages of the method shown in FIG. 8, according to various implementations of the present disclosure.

FIGS. 11A-11B illustrate schematic cross-sectional views of an exemplary 3D memory device at certain fabricating stages of the method shown in FIG. 8, according to various implementations of the present disclosure.

FIGS. 12A-12B illustrate schematic cross-sectional views of an exemplary 3D memory device at certain fabricating stages of the method shown in FIG. 8, according to various implementations of the present disclosure.

FIGS. 13A-13B illustrate schematic cross-sectional views of an exemplary 3D memory device at certain fabricating stages of the method shown in FIG. 8, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

As semiconductor technology advances, three-dimensional (3D) memory devices, such as 3D NAND memory devices, keep scaling more oxide/nitride (ON) layers of the memory cell array. With the increase of the number of array layers of the 3D architecture, the CMOS periphery circuit needs more complex and size scaling. For example, a complementary metal— oxide—semiconductor wafer (“CMOS wafer” hereinafter) is bonded with a memory cell array wafer (“array wafer” hereinafter) to form a framework of the 3D memory device. In order to achieve optimization of area, the CMOS driver circuit can be divided into two parts: a high-voltage driver part and an input/output (I/O) logic part. However, those architectures of the 3D NAND array and CMOS periphery circuits restrict the performance of the 3D NAND memory devices.

Accordingly, new 3D memory devices and fabricating methods thereof are provided to address such issues. It is noted that, the 3D memory device can be a part of a non-monolithic 3D memory device, in which components (e.g., portions of the CMOS devices and the memory cell array device) are formed separately on different wafers and then bonded in a face-to-face manner. In some implementations, as described below in connection with the figures, a first wafer including the memory cell array is flipped and faces down towards a second wafer for hybrid bonding, so that in the bonded non-monolithic 3D memory device, the first wafer is above the second wafer. It is understood that in some other implementations, the first wafer remains as the substrate of the bonded non-monolithic 3D memory device, and the second wafer is flipped and faces down towards the first wafer for hybrid bonding.

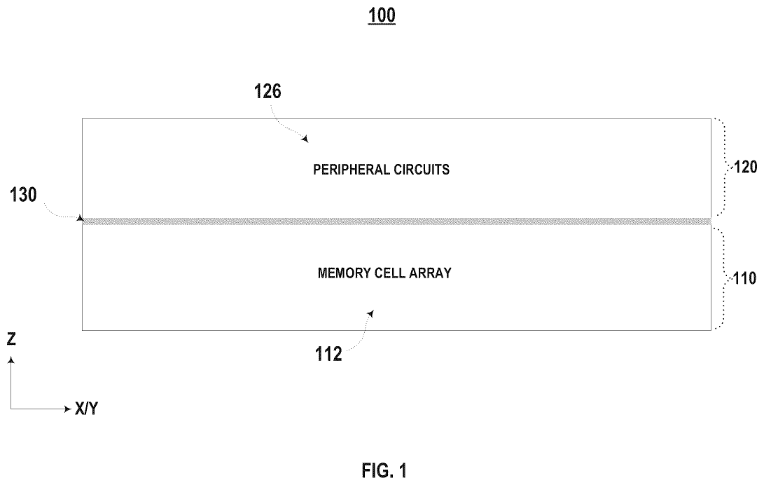

FIG. 1 illustrates a schematic view of a cross-section of a 3D memory device 100, according to some aspects of the present disclosure. 3D memory device 100 represents an example of a bonded chip. In some implementations, at least some of the components of 3D memory device 100 (e.g., first wafer/first semiconductor structure/array wafer 110 and second wafer/second semiconductor structure/CMOS wafer 120 as shown in FIG. 1) are formed separately on different substrates in parallel and then jointed to form a bonded chip (a process referred to herein as a “parallel process”).

It is noted that X/Y and Z axes are added in FIG. 1 to further illustrate the spatial relationships of the components of a semiconductor device. A substrate of a semiconductor device, e.g., 3D memory device 100, includes two lateral surfaces (e.g., a top surface and a bottom surface) extending laterally in the X and Y directions (e.g., word line direction and bit line direction). As used herein, whether one component (e.g., a layer or a device) is “on,” “above,” or “below” another component (e.g., a layer or a device) of a semiconductor device is determined relative to the substrate of the semiconductor device in the Z direction (the vertical direction or thickness direction) when the substrate is positioned in the lowest plane of the semiconductor device in the Z direction. The same notion for describing the spatial relationships is applied throughout the present disclosure.

3D memory device 100 can include a first semiconductor structure 110 including an array of memory cells (also referred to herein as a “memory cell array 112”). In some implementations, the memory cell array 112 includes an array of NAND Flash memory cells. For ease of description, a NAND Flash memory cell array may be used as an example for describing the memory cell array 112 in the present disclosure. But it is understood that the memory cell array 112 is not limited to NAND Flash memory cell array and may include any other suitable types of memory cell arrays, such as NOR Flash memory cell array, phase change memory (PCM) cell array, resistive memory cell array, magnetic memory cell array, spin transfer torque (STT) memory cell array, to name a few.

First semiconductor structure 110 can include a NAND Flash memory device in which memory cells are provided in the form of an array of 3D NAND memory strings and/or an array of two-dimensional (2D) NAND memory cells. NAND memory cells can be organized into pages or fingers, which are then organized into blocks in which each NAND memory cell is coupled to a separate line called a bit line (BL). All cells with the same vertical position in the NAND memory cell can be coupled through the control gates by a word line (WL). In some implementations, a memory plane contains a certain number of blocks that are coupled through the same bit line. First semiconductor structure 110 can include one or more memory planes.

In some implementations, the array of NAND memory cells is an array of 2D NAND memory cells, each of which includes a floating-gate transistor. The array of 2D NAND memory cells includes a plurality of 2D NAND memory strings, each of which includes a plurality of memory cells connected in series (resembling a NAND gate) and two select transistors, according to some implementations. Each 2D NAND memory string is arranged in the same plane (i.e., referring to herein a flat, two-dimensional (2D) surface, different from the term “memory plane” in the present discourse) on the substrate, according to some implementations. In some implementations, the array of NAND memory cells is an array of 3D NAND memory strings, each of which extends vertically above the substrate (in 3D) through a stack structure, e.g., a memory stack. Depending on the 3D NAND technology (e.g., the number of layers/tiers in the memory stack), a 3D NAND memory string typically includes a certain number of NAND memory cells, each of which includes a floating-gate transistor or a charge-trap transistor.

As shown in FIG. 1, 3D memory device 100 can also include one or more periphery circuits 126 of the memory cell array form in a second semiconductor structure 120 to perform all the read/program (write)/erase operations. The one or more periphery circuits 126 (a.k.a. control and sensing circuits) can include any suitable digital, analog, and/or mixed-signal circuits used for facilitating the operations of the memory cell array. For example, the one or more periphery circuits 126 can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The one or more periphery circuits 126 in second semiconductor structure 120 can use CMOS technology, e.g., which can be implemented with logic processes in any suitable technology nodes. In some implementations, second semiconductor structure 120 does not include any memory cell. In other words, second semiconductor structure 120 only includes periphery circuits 126, but not the memory cell array 112, according to some implementations. As a result, memory cell array 112 can be only included in first semiconductor structure 110, but not in second semiconductor structure 120.

As shown in FIG. 1, first semiconductor structure 110 and second semiconductor structure 120 are stacked in two different planes, according to some implementations. In some implementations, memory cell array 112 can be arranged in first semiconductor structure 110, periphery circuits 126 can be arranged in second semiconductor structure 120, and can be stacked over first semiconductor structure 110 to reduce the planar size of 3D memory device 100, compared with memory devices in which all the periphery circuits are disposed in a same plane.

As shown in FIG. 1, 3D memory device 100 further includes a bonding interface 130 vertically between first semiconductor structure 110 and second semiconductor structure 120. Bonding interface 130 can be an interface between two semiconductor structures formed by any suitable bonding technologies as described below in detail, such as hybrid bonding, anodic bonding, fusion bonding, transfer bonding, adhesive bonding, and eutectic bonding, to name a few. In some implementations, as shown in FIG. 1, second semiconductor structure 120 is bonded to first semiconductor structure 110 on opposite sides thereof.

As described below in detail, first semiconductor structure 110 and second semiconductor structure 120 can be fabricated separately (and in parallel in some implementations) by the parallel process, such that the thermal budget of fabricating one of first and second semiconductor structures 110 and 120 does not limit the processes of fabricating another one of first and second semiconductor structures 110 and 120. Moreover, a large number of interconnects (e.g., bonding contacts and/or inter-layer vias (ILVs)/through substrate vias (TSVs)) can be formed across bonding interface 130 to make direct, short-distance (e.g., micron- or submicron-level) electrical connections between first and second semiconductor structures 110 and 120, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer among memory cell array 112 and periphery circuits 126 in first and second semiconductor structures 110 and 120 can be performed through the interconnects (e.g., bonding contacts and/or ILVs/TSVs) across bonding interface 130. By vertically integrating first and second semiconductor structures 110 and 120, the chip size can be reduced, and the memory cell density can be increased.

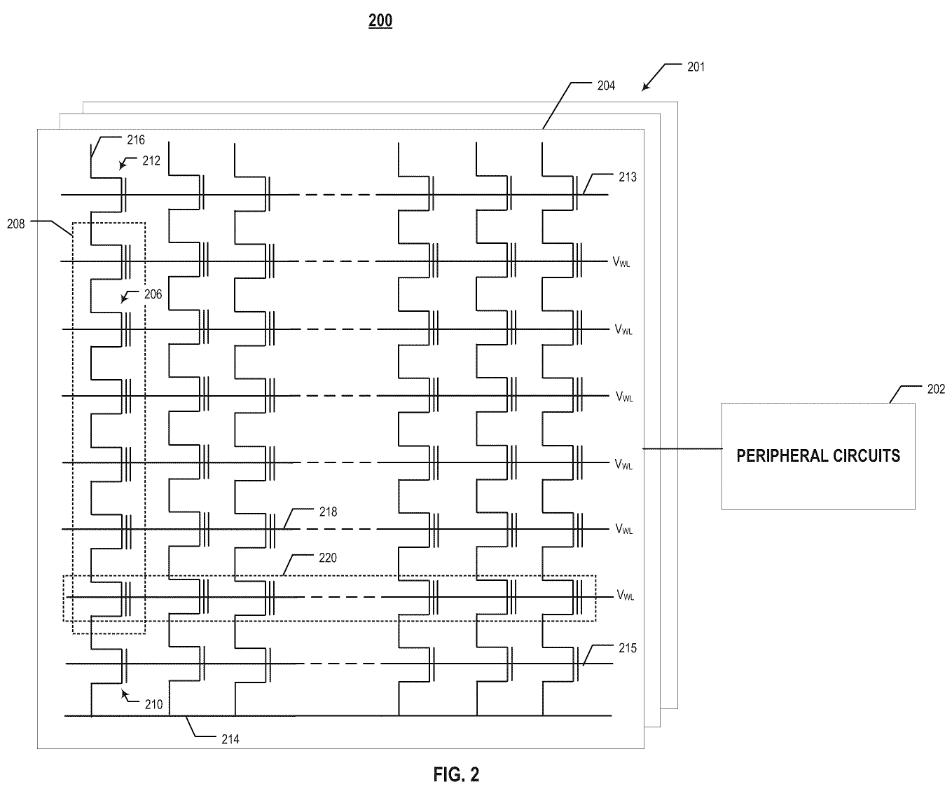

FIG. 2 illustrates a schematic circuit diagram of a memory device 200 including periphery circuits, according to some aspects of the present disclosure. Memory device 200 can include a memory cell array 201 and periphery circuits 202 coupled to memory cell array 201. 3D memory device 100 may be an example of memory device 200 in which memory cell array 201 and at least two portions of periphery circuits 202 may be included in first and second semiconductor structures 110 and 120. Memory cell array 201 can be a NAND Flash memory cell array in which memory cells 206 are provided in the form of an array of NAND memory strings 208 each extending vertically above a substrate (not shown). In some implementations, each NAND memory string 208 includes a plurality of memory cells 206 coupled in series and stacked vertically. Each memory cell 206 can hold a continuous, analog value, such as an electrical voltage or charge, that depends on the number of electrons trapped within a region of memory cell 206. Each memory cell 206 can be either a floating gate type of memory cell including a floating-gate transistor or a charge trap type of memory cell including a charge-trap transistor.

In some implementations, each memory cell 206 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 206 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 2, each NAND memory string 208 can include a source select gate (SSG) transistor 210 at its source end and a drain select gate (DSG) transistor 212 at its drain end. SSG transistor 210 and DSG transistor 212 can be configured to activate selected NAND memory strings 208 (columns of the array) during read and program operations. In some implementations, SSG transistors 210 of NAND memory strings 208 in the same block 204 are coupled through a same source line (SL) 214, e.g., a common SL, for example, to the ground. DSG transistor 212 of each NAND memory string 208 is coupled to a respective bit line 216 from which data can be read or programmed via an output bus (not shown), according to some implementations. In some implementations, each NAND memory string 208 is configured to be selected or deselected by applying a select voltage (e.g., above the threshold voltage of DSG transistor 212) or a deselect voltage (e.g., 0 V) to respective DSG transistor 212 through one or more DSG lines 213 and/or by applying a select voltage (e.g., above the threshold voltage of SSG transistor 210) or a deselect voltage (e.g., 0 V) to respective SSG transistor 210 through one or more SSG lines 215.

As shown in FIG. 2, NAND memory strings 208 can be organized into multiple blocks 204, each of which can have a common source line 214. In some implementations, each block 204 is the basic data unit for erase operations, i.e., all memory cells 206 on the same block 204 are erased at the same time. Memory cells 206 of adjacent NAND memory strings 208 can be coupled through word lines 218 that select which row of memory cells 206 is affected by read and program operations. In some implementations, each word line 218 is coupled to a page 220 of memory cells 206, which is the basic data unit for program and read operations. The size of one page 220 in bits can correspond to the number of NAND memory strings 208 coupled by word line 218 in one block 204. Each word line 218 can include a plurality of control gates (gate electrodes) at each memory cell 206 in respective page 220 and a gate line coupling the control gates.

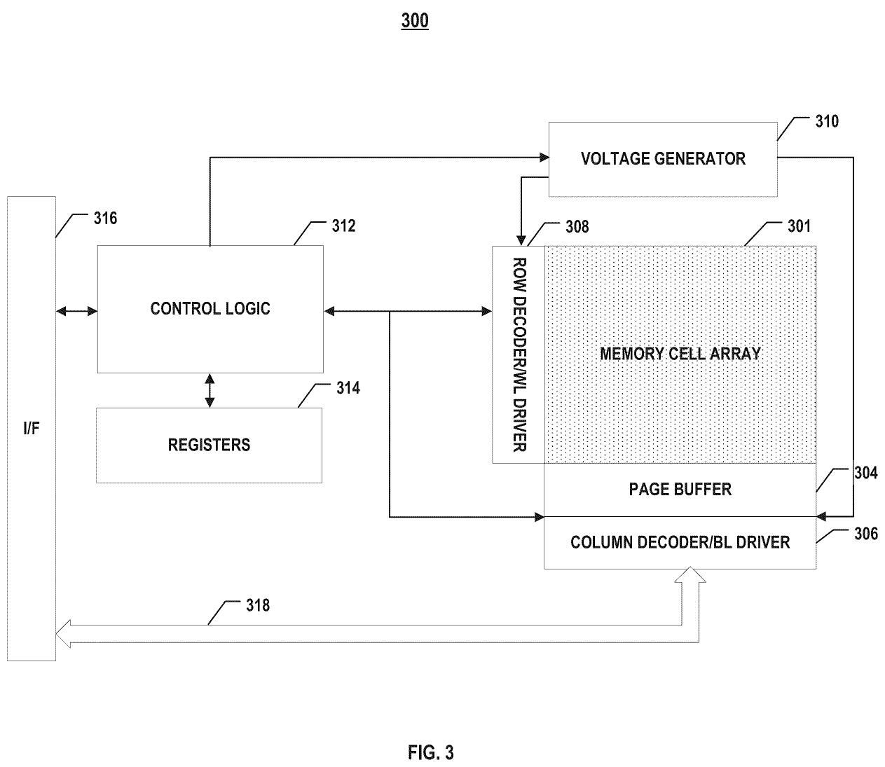

Referring to FIG. 2, periphery circuits 202 can be coupled to memory cell array 201 through bit lines 216, word lines 218, source lines 214, SSG lines 215, and DSG lines 213. As described above, periphery circuits 202 can include any suitable circuits for facilitating the operations of memory cell array 201 by applying and sensing voltage signals and/or current signals through bit lines 216 to and from each target memory cell 206 through word lines 218, source lines 214, SSG lines 215, and DSG lines 213. Periphery circuits 202 can include various types of periphery circuits formed using CMOS technologies. For example, FIG. 3 illustrates some exemplary periphery circuits 202 including a page buffer 304, a column decoder/bit line driver 306, a row decoder/word line driver 308, a voltage generator 310, control logic 312, registers 314, an interface (UF) 316, and a data bus 318. It is understood that in some examples, additional periphery circuits 202 may be included as well.

Page buffer 304 can be configured to buffer data read from or programmed to memory cell array 201 according to the control signals of control logic 312. In one example, page buffer 304 may store one page of program data (write data) to be programmed into one page 220 of memory cell array 201. In another example, page buffer 304 also performs program verify operations to ensure that the data has been properly programmed into memory cells 206 coupled to selected word lines 218.

Row decoder/word line driver 308 can be configured to be controlled by control logic 312 and select block 204 of memory cell array 201 and a word line 218 of selected block 204. Row decoder/word line driver 308 can be further configured to drive memory cell array 201. For example, row decoder/word line driver 308 may drive memory cells 206 coupled to the selected word line 218 using a word line voltage generated from voltage generator 310.

Column decoder/bit line driver 306 can be configured to be controlled by control logic 312 and select one or more 3D NAND memory strings 208 by applying bit line voltages generated from voltage generator 310. For example, column decoder/bit line driver 306 may apply column signals for selecting a set of N bits of data from page buffer 304 to be outputted in a read operation.

Control logic 312 can be coupled to each periphery circuit 202 and configured to control operations of periphery circuits 202. Registers 314 can be coupled to control logic 312 and include status registers, command registers, and address registers for storing status information, command operation codes (OP codes), and command addresses for controlling the operations of each periphery circuit 202.

Interface 316 can be coupled to control logic 312 and configured to interface memory cell array 201 with a memory controller (not shown). In some implementations, interface 316 acts as a control buffer to buffer and relay control commands received from the memory controller and/or a host (not shown) to control logic 312 and status information received from control logic 312 to the memory controller and/or the host. Interface 316 can also be coupled to page buffer 304 and column decoder/bit line driver 306 via data bus 318 and act as an I/O interface and a data buffer to buffer and relay the program data received from the memory controller and/or the host to page buffer 304 and the read data from page buffer 304 to the memory controller and/or the host. In some implementations, interface 316 and data bus 318 are parts of an I/O circuit of periphery circuits 202.

Voltage generator 310 can be configured to be controlled by control logic 312 and generate the word line voltages (e.g., read voltage, program voltage, pass voltage, local voltage, and verification voltage) and the bit line voltages to be supplied to memory cell array 201. In some implementations, voltage generator 310 is part of a voltage source that provides voltages at various levels of different periphery circuits 202 as described below in detail. Consistent with the scope of the present disclosure, in some implementations, the voltages provided by voltage generator 310, for example, to row decoder/word line driver 308, column decoder/bit line driver 306, and page buffer 304 are above certain levels that are sufficient to perform the memory operations. For example, the voltages provided to the page buffer circuits in page buffer 304 and/or the logic circuits in control logic 312 may be between 1.3 V and 5 V, such as 3.3 V, and the voltages provided to the driving circuits in row decoder/word line driver 308 and/or column decoder/bit line driver 306 may be between 5 V and 30 V.

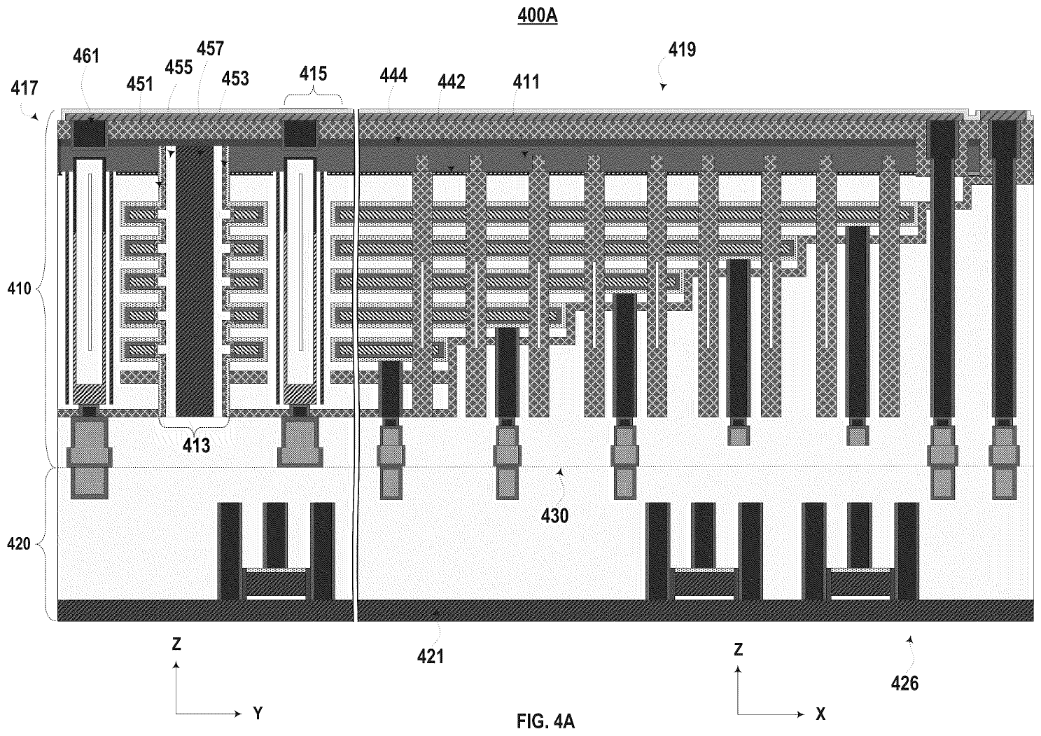

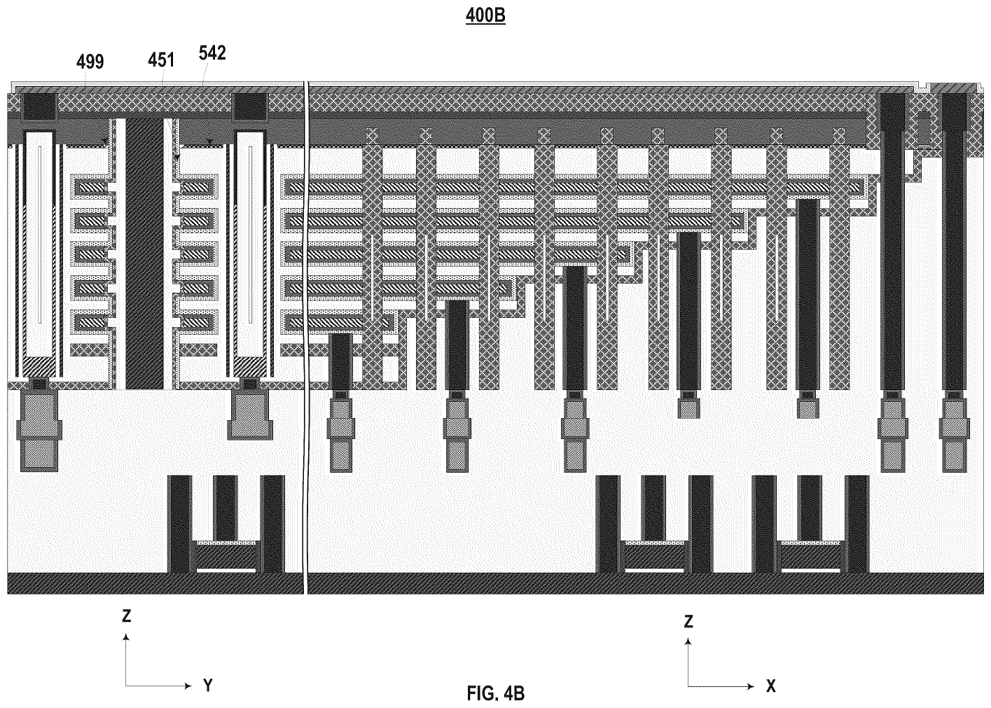

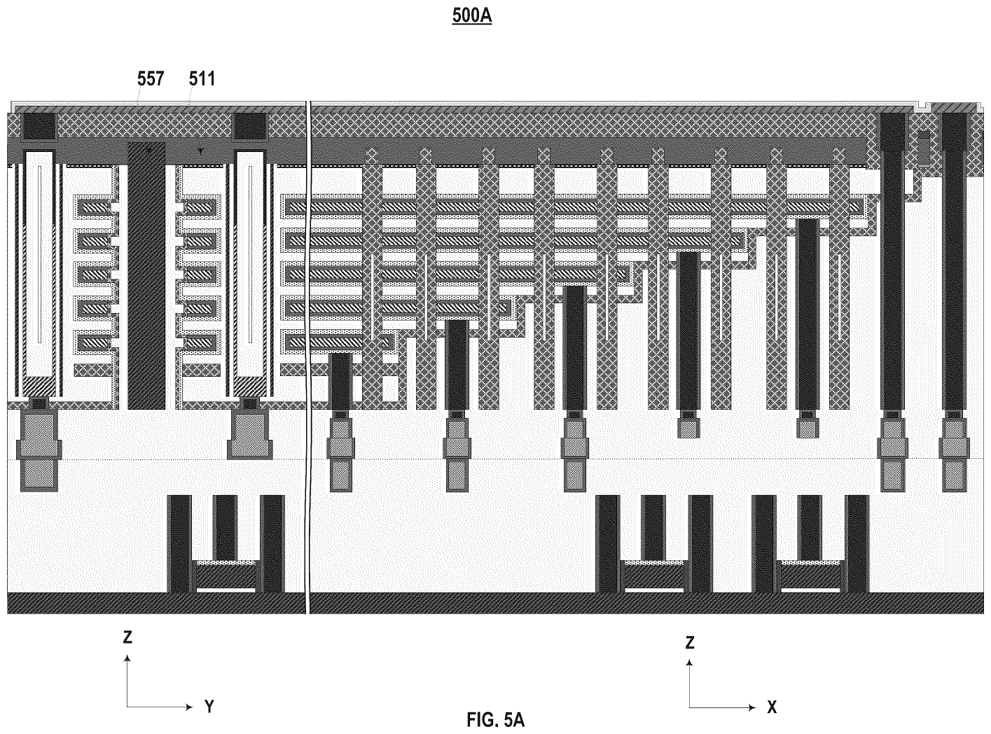

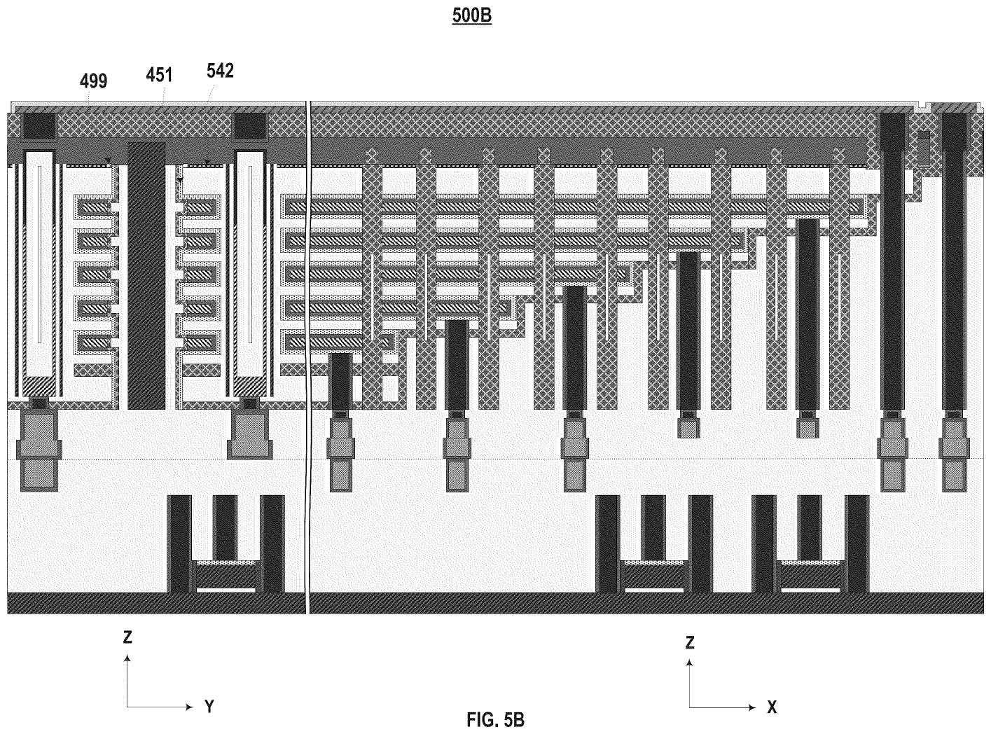

FIGS. 4A-4B and 5A-5B illustrate schematic structural diagrams of exemplary 3D memory devices in a cross-sectional side view, according to various implementations of the present disclosure. It is noted that X, Y, and Z axes are included in FIGS. 4A-4B and 5A-5B to further illustrate the spatial relationship of the components in 3D memory devices.

As shown in FIG. 4A, in some implementations, 3D memory device 400A is a bonded chip including a first semiconductor structure 410 and a second semiconductor structure 420 stacked over first semiconductor structure 410. First and second semiconductor structures 410 and 420 are jointed at a bonding interface 430 therebetween, according to some implementations.

As shown in FIG. 4A, first semiconductor structure 410 can include semiconductor layer 411, which can include silicon (e.g., single crystalline silicon, c-Si, or poly crystalline silicon, etc.), silicon germanium (SiGe), gallium arsenide (GaAs), germanium (Ge), silicon-on-insulator (SOI), or any other suitable materials. In some implementations, first semiconductor structure 410 further includes a barrier layer 442, which can include single crystalline silicon, polysilicon, a high-k dielectric, or a metal, and is used for blocking ions implanting during fabricating processes. In some implementations, first semiconductor structure 410 of 3D memory device 400A further includes a memory cell array 417. The structure of memory cell array 417 will be described in detail below.

As shown in FIG. 4A, first semiconductor structure 410 of 3D memory device 400A can further include a bonding layer at bonding interface 430 and above the interconnect layer. Bonding layer can include a plurality of bonding contacts and dielectrics electrically isolating bonding contacts. Bonding contacts can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. The bonding contacts and surrounding dielectrics in bonding layer can be used for hybrid bonding.

As shown in FIG. 4A, second semiconductor structure 420 of 3D memory device 100 can include substrate 421, which can include silicon (e.g., single crystalline silicon, c-Si), silicon germanium (SiGe), gallium arsenide (GaAs), germanium (Ge), silicon-on-insulator (SOI), or any other suitable materials. Second semiconductor structure 420 of 3D memory device 400A can include periphery circuit 426 on substrate 421. In some implementations, periphery circuit 426 can include any suitable periphery circuits 202 discussed above. In some implementations, periphery circuit 426 can include a plurality of transistors located on substrate 421. Although not labeled in FIG. 4A, isolation regions (e.g., STIs) and doped regions (e.g., source regions and drain regions of the transistors) can be formed in substrate 421.

Similar to first semiconductor structure 410, second semiconductor structure 420 of 3D memory device 400A can also include a bonding layer at bonding interface 430. Bonding layer can include a plurality of bonding contacts and dielectrics electrically isolating bonding contacts. Bonding contacts can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. Bonding contacts and surrounding dielectrics in bonding layer can be used for hybrid bonding. Bonding contacts are in contact with bonding contacts at bonding interface 430, according to some implementations.

As shown in FIG. 4A, second semiconductor structure 420 can be bonded on top of first semiconductor structure 410 in a face-to-face manner at bonding interface 430. In some implementations, bonding interface 430 is a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 430 is the place at which first semiconductor structure 410 and second semiconductor structure 420 are met and bonded.

In some implementations, 3D memory device 400A is a NAND Flash memory device in which memory cells are provided in the form of an array of NAND memory strings. Each NAND memory string can include a respective channel structure 415. As shown in FIG. 4A, each channel structure 425 can extend vertically through a plurality of pairs each including a stack conductive layer and a stack dielectric layer. The interleaved stack conductive layers and stack dielectric layers are part of memory cell array 417. The number of the pairs of stack conductive layers and stack dielectric layers in memory cell array 417 determines the number of memory cells in 3D memory device 400A. It is understood that in some implementations, memory cell array 417 may have a staircase structure 419, which includes a plurality of memory decks stacked over one another. The numbers of the pairs of stack conductive layers and stack dielectric layers in each memory deck can be the same or different.

Memory cell array 417 can include a plurality of interleaved stack conductive layers and stack dielectric layers. Stack conductive layers and stack dielectric layers in memory cell array 417 can alternate in the vertical direction. In other words, except the ones at the top or bottom of memory cell array 417, each stack conductive layer can be adjoined by two stack dielectric layers on both sides, and each stack dielectric layer can be adjoined by two stack conductive layers on both sides. Stack conductive layers can include conductive materials including, but not limited to, W, Co, Cu, Al, polycrystalline silicon (polysilicon), doped silicon, silicides, or any combination thereof. Each stack conductive layer can include a gate electrode (gate line) surrounded by an adhesive layer and a gate dielectric layer. The gate electrode of stack conductive layer can extend laterally as a word line, ending at one or more staircase structures of memory cell array 417. Stack dielectric layers can include dielectric materials including, but not limited to, silicon oxide, silicon nitride, silicon oxynitride, or any combination thereof.

In some implementations, each channel structure 425 can have a cylinder shape (e.g., a pillar shape), and can extend vertically through interleaved stack conductive layers and stack dielectric layers of memory cell array 417 and in contact with semiconductor layer 411. Each channel structure 425 includes a channel hole filled with a composite functional layer, a semiconductor channel, and a capping structure that are arranged radially from the center toward the outer surface of the pillar in this order, according to some implementations. The capping structure can include dielectric materials, such as silicon oxide, and/or an air gap. The composite functional layer can radially circumscribe the semiconductor channel along the lateral direction. A composite functional layer can be formed laterally between the semiconductor channel and memory cell array 417. In some implementations, the semiconductor channel includes silicon, such as amorphous silicon, polysilicon, or single crystalline silicon. In some implementations, the semiconductor channel can include a doped portion and an undoped portion. In some implementations, the doped portion of the semiconductor channel can be in direct contact with semiconductor layer 411.

In some implementations, memory cell array 417 can further include one or more gate line slit (GLS) structures 413 each vertically penetrating through the memory cell array 417 and barrier layer 442, and extending into semiconductor layer 411, and can extend laterally in a straight line along a word line direction (i.e., X direction) between two arrays of channel structures 415. Each GLS structure 413 can include a conductive structure 457 sandwiched by a high-k dielectric layer 451, a first gate line spacer (GLSP) layer 453, and a second GLSP layer 455. High-k dielectric layer 451 can include any suitable dielectric material having a relative dielectric constant k higher than the dielectric constant of silicon dioxide (i.e., 3.9), such as hafnium silicate, zirconium silicate, hafnium dioxide, zirconium dioxide, etc. First GLSP layer 453 can be a low temperature oxide layer formed by a low temperature (e.g., lower than 400° C.) oxidization process, and a second GLSP layer 455 can be a high temperature oxide layer formed by a high temperature (e.g., higher than 400° C.) oxidization process. Filling structure 457 can be a conductive wall comprising any suitable conductive materials, such as tungsten (W), cobalt (Co), copper (Cu), aluminum (Al), etc., or any combination thereof.

In some implementations as shown in FIG. 4A, filling structure 457 is in electric connection with semiconductor layer 411 through connecting layer 444, which includes any suitable conductive materials including, but not limited to, W, Co, Cu, Al, doped silicon, silicides, or any combination thereof. In some other implementations as shown in FIG. 5A, filling structure 557 of 3D memory device 500A extends vertically into semiconductor layer 511. Since filling structure 557 is in direct contact with semiconductor layer 511, the connecting layer can be omitted. It is noted that, in 3D memory devices 400A and 500A shown in FIGS. 4A and 5A, barrier layer 442 can include high-k dielectric material, and thus can be in direct contact with high-k dielectric layer 451. In some other implementations as shown in FIGS. 4B and 5B, barrier layer 542 can include single crystalline silicon, polysilicon or metal material. In such implementations, 3D memory devices 400B and 500B can further include an oxide structure 499 between barrier layer 919 and high-k dielectric layer 931.

Referring back to FIG. 4A, in some implementations, first semiconductor structure 410 of 3D memory device 400A further includes an interconnect layer between above periphery circuit 426 and memory cell array 417 to transfer electrical signals to periphery circuits. The interconnect layer can include a plurality of interconnects (also referred to herein as contacts), including lateral interconnect lines and vertical interconnect access (VIA) contacts. As used herein, the term interconnects can broadly include any suitable types of interconnects, such as middle-end-of-line (MEOL) interconnects and back-end-of-line (BEOL) interconnects. The interconnect layer can further include one or more interlayer dielectric (ILD) layers (a.k.a. intermetal dielectric (IMD) layers) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, W, Co, Cu, or Al, silicides, or any combination thereof. The ILD layers in the interconnect layer can include dielectric materials including, but not limited to, silicon oxide, silicon nitride, silicon oxynitri de, low dielectric constant (low-k) dielectrics, or any combination thereof.

Instead of the front side contacts/pads, 3D memory device 400A can include one or more backside contacts/pads 461 above and in contact with semiconductor layer 411, as shown in FIG. 4A. Contacts/pads 461 and memory cell array 417 can be disposed at opposite sides of semiconductor layer 411 and thus, viewed as a “backside” contacts/pads. In some implementations, contacts/pads 461 can be formed by any suitable BEOL method and electrically connected to the semiconductor channel of channel structures 425 through semiconductor layer 411. Contacts/pads 461 can include any suitable types of contacts and/or pads. In some implementations, contacts/pads 461 can include a VIA contact, a wall-shaped contact extending laterally, one or more conductive layers, such as a metal layer (e.g., W, Co, Cu, or Al) or a silicide layer surrounded by an adhesive layer (e.g., titanium nitride (TiN)), etc. In some implementations, one or more contacts/pads 461 may further include a spacer (e.g., a dielectric layer) to electrically separate the one or more contacts/pads 461 from semiconductor layer 411.

Although exemplary 3D memory devices 400A, 400B, 500A, and 500B are shown in FIGS. 4A-4B and 5A-5B, it is understood that by varying the relative positions of first and second semiconductor structures 410 and 420, the usage of various interconnects, contacts, and/or the pad-out locations (e.g., through first semiconductor structure 410 and/or second semiconductor structure 420), any other suitable architectures of 3D memory devices may be applicable in the present disclosure without further detailed elaboration.

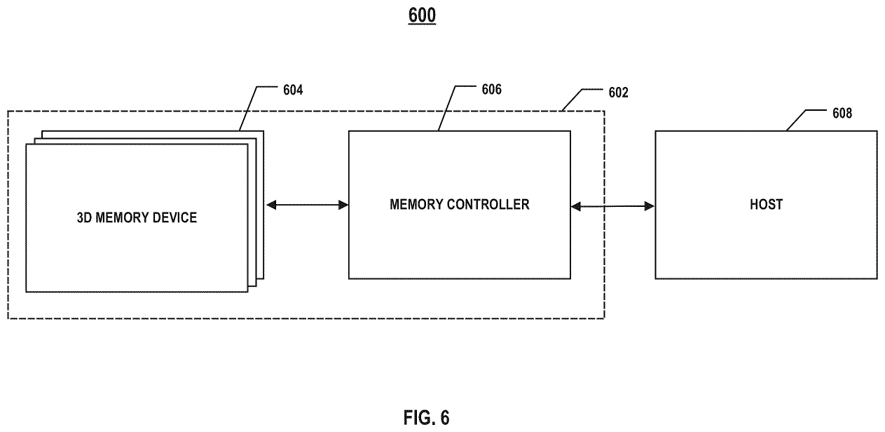

FIG. 6 illustrates a block diagram of an exemplary system 600 having a 3D memory device, according to some aspects of the present disclosure. System 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, system 600 can include a host 608 and a memory system 602 having one or more 3D memory devices 604 and a memory controller 606. Host 608 can be a processor of an electronic device, such as a central processing unit (CPU), or a system-on-chip (SoC), such as an application processor (AP). Host 608 can be configured to send or receive data to or from 3D memory devices 604.

3D memory device 604 can be any 3D memory devices disclosed herein, such as 3D memory devices 100, 400A, 400B, 500A and 500B shown in FIGS. 1, 4A-4B and 5A-5B. In some implementations, each 3D memory device 604 includes a NAND Flash memory. Consistent with the scope of the present disclosure, the semiconductor channel of 3D memory device 604 can be partially doped such that part of the semiconductor channel that forms the source contact is highly doped to lower the potential barrier while leaving another part of the semiconductor channel that forms the memory cells remaining undoped or lowly doped. One end of each channel structure of 3D memory device 604 can be opened from the backside to expose the doped part of the respective semiconductor channel. 3D memory device 604 can further include a doped semiconductor layer electrically connecting the exposed doped parts of the semiconductor channels to further reduce the contact resistance and sheet resistance. Moreover, 3D memory device 604 can include a composite dielectric film having a gate dielectric portion that faces the source select gate line(s). As a result, the electric performance of 3D memory device 604 can be improved, which in turn improves the performance of memory system 602 and system 600, e.g., achieving higher operation speed.

Memory controller 606 (a.k.a., a controller circuit) is coupled to 3D memory device 604 and host 608 and is configured to control 3D memory device 604, according to some implementations. Memory controller 606 can manage the data stored in 3D memory device 604 and communicate with host 608. In some implementations, memory controller 606 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed for operating in a high duty-cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604. Memory controller 606 can communicate with an external device (e.g., host 608) according to a particular communication protocol. For example, memory controller 606 may communicate with the external device through at least one of various interface protocols, such as a USB protocol, an MMC protocol, a periphery component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

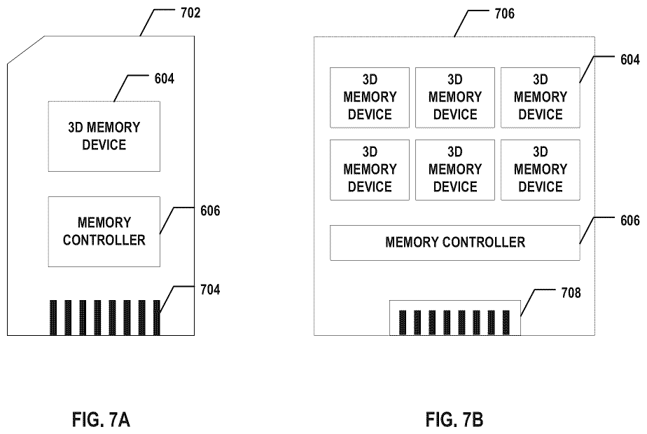

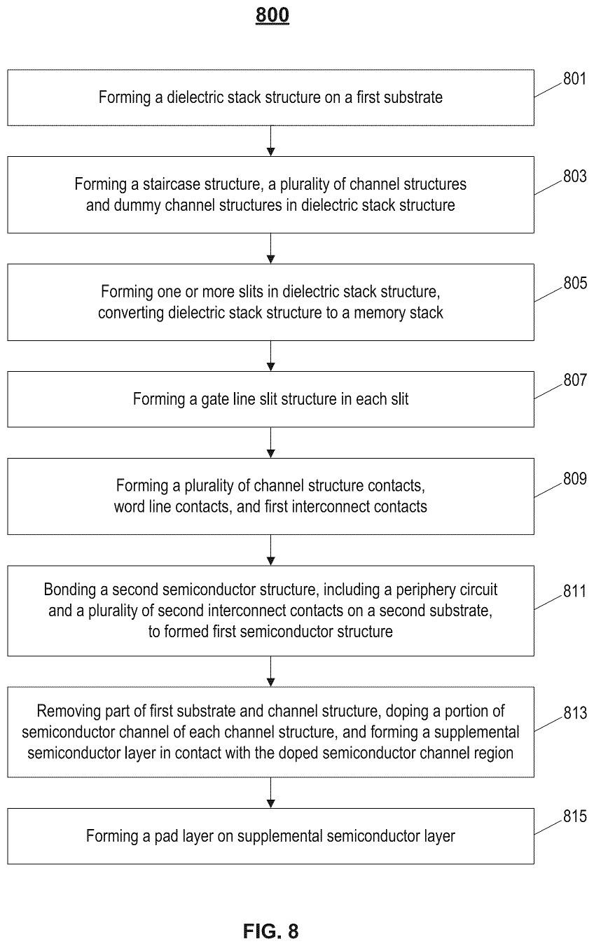

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 7A, memory controller 606 and a single 3D memory device 604 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 702 can further include a memory card connector 704 electrically coupling memory card 702 with a host (e.g., host 608 in FIG. 7). In another example as shown in FIG. 8, memory controller 606 and multiple 3D memory devices 604 may be integrated into an SSD 706. SSD 706 can further include an SSD connector 708 electrically coupling SSD 706 with a host (e.g., host 608 in FIG. 7). In some implementations, the storage capacity and/or the operation speed of SSD 706 is greater than those of memory card 702.

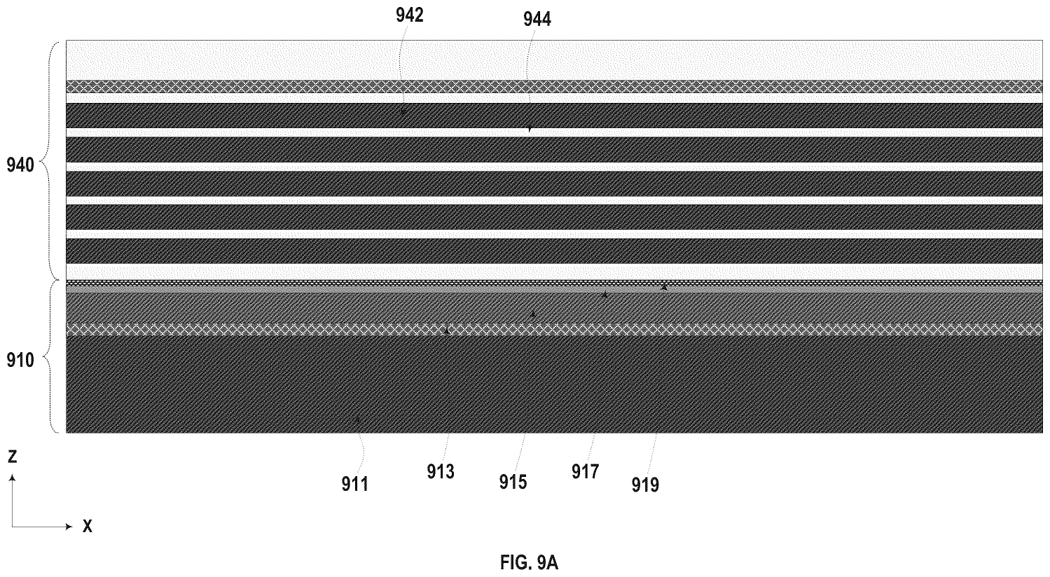

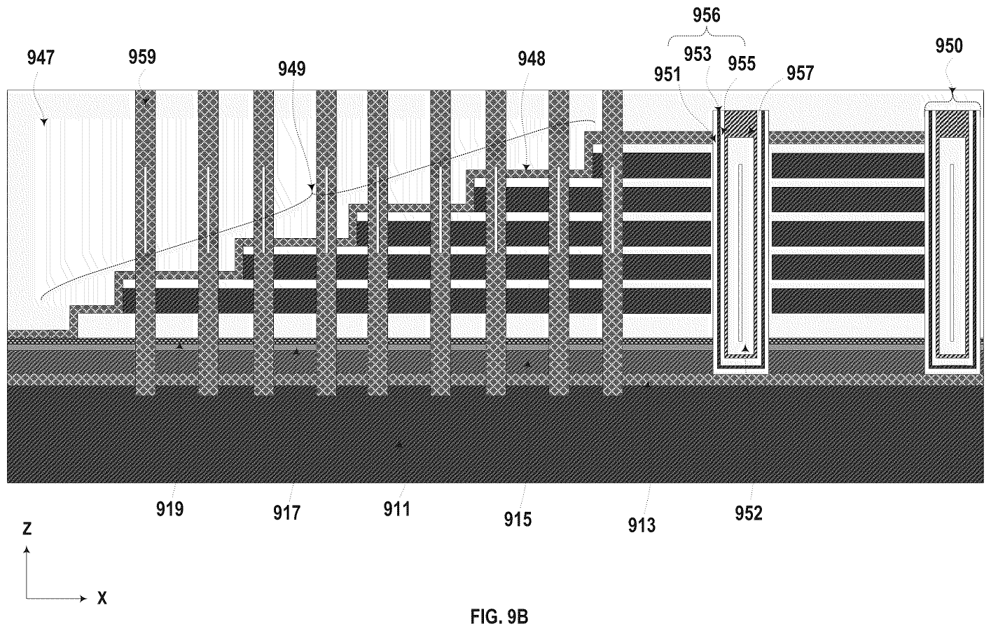

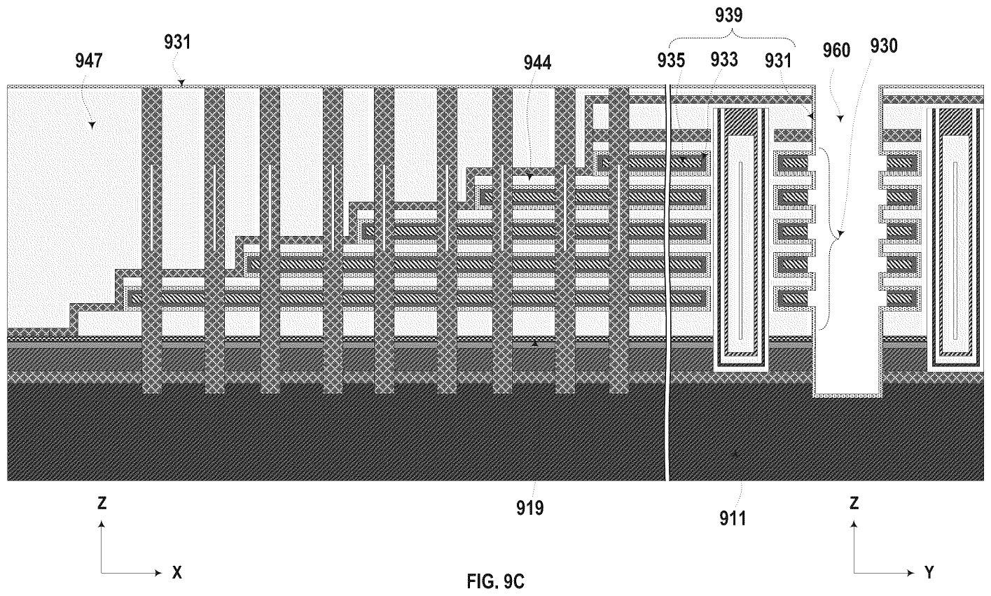

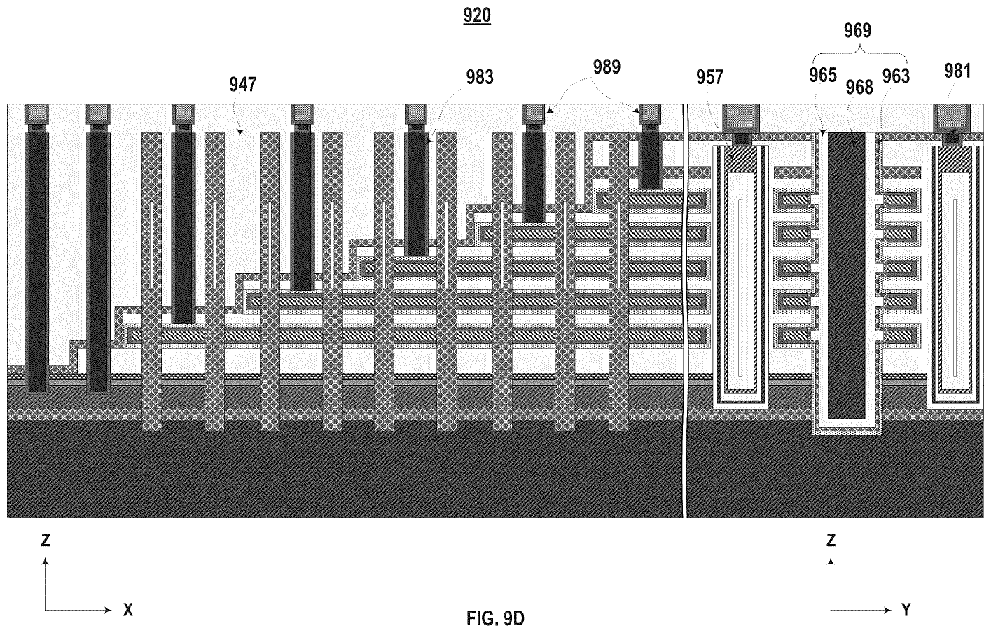

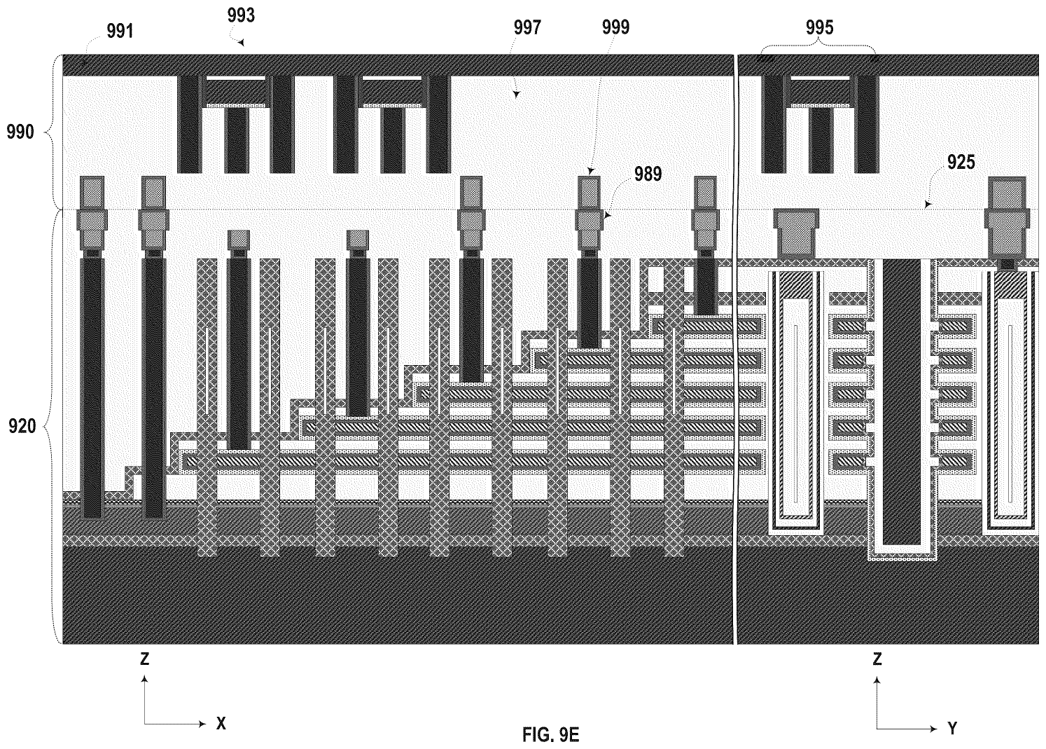

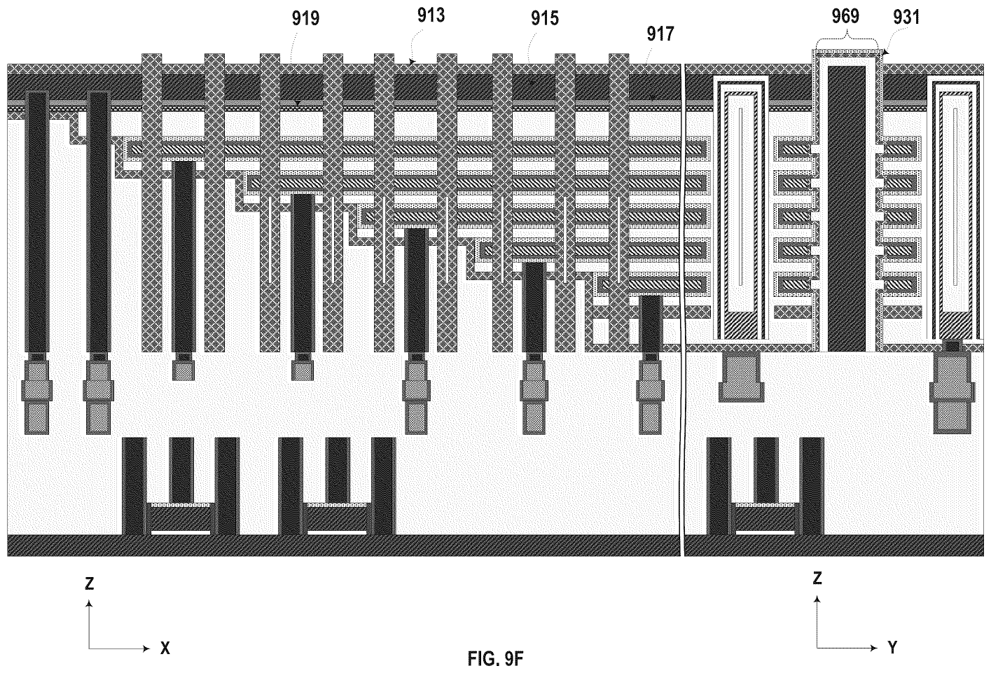

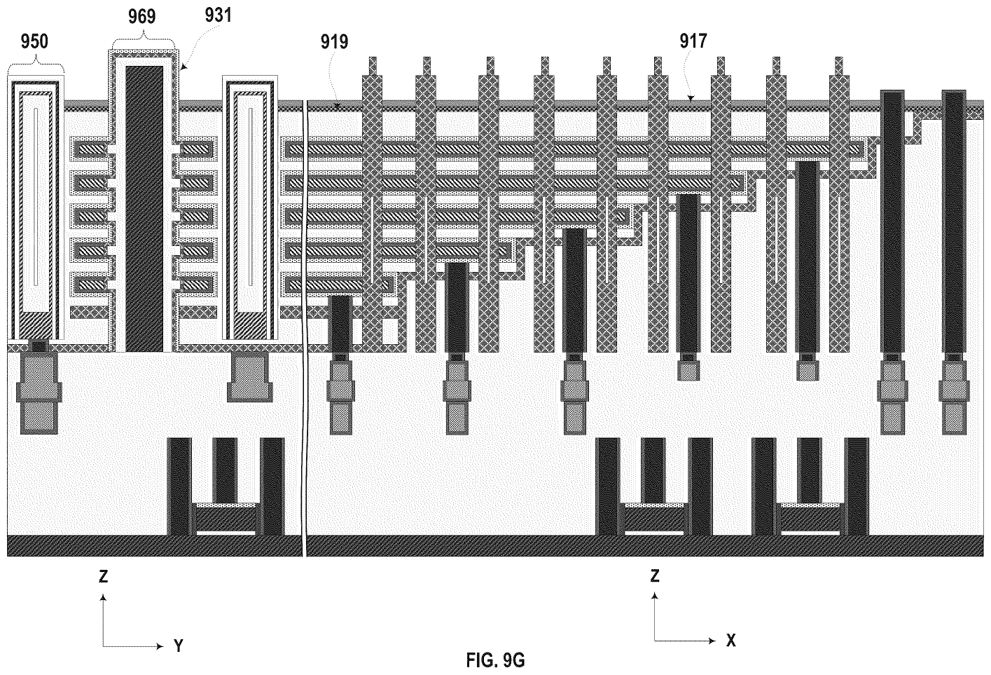

Referring to FIG. 8, a flow diagram of an exemplary method for forming a 3D memory device is illustrated in accordance with some implementations of the present disclosure. It should be understood that the operations shown in FIG. 8 are not exhaustive and that other operations can be performed as well before, after, or between any of the illustrated operations. Further, some of the operations may be performed simultaneously, or in a different order than shown in FIG. 8. FIGS. 9A-9G, 10A-10B, 11A-11B, 12A-12B, and 13A-13B illustrate schematic cross-sectional views of an exemplary 3D memory device at certain fabricating stages of the method shown in FIG. 8 according to some implementations of the present disclosure.

Referring to FIG. 8, method 800 can start at operation 801, in which a dielectric stack structure can be formed on a first substrate.

As shown in FIG. 9A, in some implementations, first substrate 910 can be a stack structure including a sacrificial substrate 911, a first stop layer 913, an initial semiconductor layer 915, a second stop layer 917, and a barrier layer 919. Sacrificial substrate 911 can be any suitable carrier substrate, such as a silicon substrate or a carrier substrate, made of any suitable materials, such as glass, sapphire, plastic, to name a few, to reduce the cost of the substrate. First stop layer 913 can be formed above sacrificial substrate 911, and can act as a chemical mechanical polishing (CMP)/etch stop layer when removing sacrificial substrate 911 in subsequent process from the backside and thus, may include any suitable materials other than the material of sacrificial substrate 911, such as silicon nitride or silicon oxide. Initial semiconductor layer 915 can be formed to cover first stop layer 913. In some implementations, initial semiconductor layer 915 can include silicon. Second stop layer 917 is formed to cover initial semiconductor layer 915. Second stop layer 917 can act as an etch stop layer when removing portions of initial semiconductor layer 915 from the backside and thus, may include any suitable materials other than the material of initial semiconductor layer 915, such as silicon nitride or silicon oxide. Barrier layer 919 is formed on second stop layer 917. Barrier layer 919 can include polysilicon, a high-k dielectric, or a metal, and can be used for blocking ions implanting in subsequent ion implantation processes.

In some implementations, first substrate 910 including sacrificial substrate 911, first stop layer 913, initial semiconductor layer 915, second stop layer 917, and barrier layer 919 can be sequentially formed using one or more thin film deposition processes including, but not limited to, Chemical Vapor Deposition (CVD), Physical Vapor Deposition (PVD), Atomic Layer Deposition (ALD), or any combination thereof. It is understood that in some examples, pad oxide layers (e.g., silicon oxide layers, not shown) may be formed between sacrificial substrate 911, first stop layer 913, initial semiconductor layer 915, second stop layer 917, and barrier layer 919 to relax the stress between different layers and avoid peeling.

As illustrated in FIG. 9A, in some implementations, dielectric stack structure 940 including interleaved stack dielectric layers 944 and stack sacrificial layers 942 can be formed on first substrate 910. Dielectric stack structure 940 can include a plurality pairs of a first dielectric layer 942 (referred to herein as “stack sacrificial layer” 942) and a second dielectric layer 944 (referred to herein as “stack dielectric layer” 944, together referred to herein as “dielectric layer pairs”). Stack dielectric layers 944 and stack sacrificial layers 942 can be alternatingly deposited on first substrate 910 to form dielectric stack structure 940. In some implementations, each stack dielectric layer 944 includes a layer of silicon oxide, and each stack sacrificial layer 942 includes a layer of silicon nitride. Dielectric stack structure 940 can be formed by one or more thin film deposition processes including, but not limited to, CVD, PVD, ALD, or any combination thereof.

Referring back to FIG. 8, method 800 can then proceed to operation 803, in which a staircase structure, a plurality of channel structures, and dummy channel structures can be formed in the dielectric stack structure.

As illustrated in FIG. 9B, staircase structure 949 can be formed on one side of dielectric stack structure 940. The staircase structure 949 can be formed by performing a plurality of so-called “trim-etch” cycles to the dielectric layer pairs of dielectric stack structure 940 toward first substrate 910. Due to the repeated trim-etch cycles applied to the dielectric layer pairs of dielectric stack structure 940, dielectric stack structure 940 can have one or more tilted edges and a top dielectric layer pair shorter than the bottom one, as shown in FIG. 9B. A staircase insulating layer 948 can be formed to cover the staircase structure 949. In some implementations, a deposition process can be performed to form the staircase insulating layer 948. In some implementations, a filling insulating structure 947 can be formed to cover staircase structure 949 and dielectric stack structure 940. A CMP process can be performed to planarize the top surface of the filling insulating structure 947. In some implementations, the region of the formed staircase structure 949 can be referred to as a staircase region.

A plurality of channel structures 950 each extending through and beyond the dielectric stack structure 940, and the filling insulating structure 947 can be formed. Each channel structure 950 can include functional layer 956 and semiconductor channel 957. In some implementations, functional layer 956 is a composite dielectric layer including a blocking layer 951, a storage layer 953, and a tunneling layer 955. In some implementations, the plurality of channel structures 950 can be arranged in an array form in a core region.

To form the channel structure 950, a channel hole extending through dielectric stack structure 940, filling insulating structure 947, and partial first substrate 910 is formed. In some implementations, a plurality of channel holes are formed, such that each channel hole becomes the location for growing an individual channel structure 950 in the subsequent process. In some implementations, fabrication processes for forming the channel holes of channel structures 950 include wet etching and/or dry etching. As illustrated in FIG. 9B, each channel hole can penetrate barrier layer 919, second stop layer 917, and initial semiconductor layer 915, and stop at first stop layer 913.

Blocking layer 951, storage layer 953, tunneling layer 955, and semiconductor channel 957 are sequentially formed in this order along sidewalls and the bottom surface of each channel hole. In some implementations, blocking layer 951, storage layer 953, and tunneling layer 955 are first deposited along the sidewalls and bottom surface of the channel hole in this order using one or more thin film deposition processes, such as ALD, CVD, PVD, any other suitable processes, or any combination thereof, to form the memory film. Semiconductor channel 957 then can be formed by depositing a semiconductor material, such as polysilicon (e.g., undoped polysilicon), over third dielectric layer 955 using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (an “ONOS” structure) are sequentially deposited to form blocking layer 951, storage layer 953, tunneling layer 955, and semiconductor channel 957.

In some implementations, a capping structure 952 is formed in the channel hole to fully or partially fill the channel hole (e.g., without or with an air gap). Capping structure 952 can be formed by depositing a dielectric material, such as silicon oxide, using one or more thin film deposition processes, such as ALD, CVD, PVD, any other suitable processes, or any combination thereof. In some implementations, a channel plug (not shown) can then be formed in the top portion of the channel hole for connecting semiconductor channel 957 of each channel structure 950.

As illustrated in FIG. 9B, a plurality of dummy channel structures 959 can be formed extending through and beyond filling insulating structure 947, staircase structure 949, and partial first substrate 910. In some implementations, a plurality of dummy channel holes are formed in any suitable positions, such that each dummy channel hole becomes the location for growing an individual dummy channel structure 959 in the subsequent process. In some implementations, fabrication processes for forming the dummy channel holes of dummy channel structures 959 include wet etching and/or dry etching. A deposition process can then be performed to fill the multiple dummy channel holes with any suitable dielectric material, such as SiO2. As such, multiple dummy channel structures 959 can be formed to provide mechanical support for the 3D memory array structures.

Referring back to FIG. 8, method 800 can then proceed to operation 805, in which one or more slits can be formed in the dielectric stack structure and extending along a word line direction, the dielectric stack structure can be converted to a memory stack. That is, the stack sacrificial layers in the dielectric stack structure can be replaced by multiple gate structures.

As shown in the cross-sectional view of the core region in Y-Z plane in FIG. 9C, in some implementations, each slit 960 can vertically penetrate through dielectric stack structure 940 and filling insulating structure 947, and extend vertically into first substrate 910, and can extend laterally in a straight line along a word line direction (i.e., X direction) between two arrays of channel structures 950. The one or more slits 960 can be formed by forming a mask layer (not shown) over dielectric stack structure 940 and patterning the mask using, e.g., photolithography, to form openings corresponding to the multiple slits in the patterned mask layer. A suitable etching process, e.g., dry etch and/or wet etch, can be performed to remove portions of dielectric stack structure 940 and first substrate 910 exposed by the openings until the one or more slits expose sacrificial substrate 911. It is noted that in the present disclosure of some implementations, the etching process for forming slit 960 does not need to consider gouging, thereby allowing a larger process window. The mask layer can be removed after the formation of the multiple slits.

A gate replacement can then be performed through the one or more slits 960 to replace stack sacrificial layers 942 in dielectric stack structure 940 by multiple gate structures 939. After the gate replacement, dielectric stack structure 940 can become a memory stack 930, as shown in FIG. 9C. In some implementations, stack sacrificial layers 942 in dielectric stack structure 940 can be removed by applying etchants through the one or more slits 960. Any suitable etching process, e.g., an isotropic dry etch or a wet etch, can be used to remove stack sacrificial layers 942. The etching process can have sufficiently high etching selectivity of the material of stack sacrificial layers 942 over the materials of the stack dielectric layers 944, such that the etching process can have minimal impact on the stack dielectric layers 944. The isotropic dry etch and/or the wet etch can remove stack sacrificial layers 942 in various directions to expose the top and bottom surfaces of each stack dielectric layer 944. As such, multiple horizontal trenches can then be formed interleaved between stack dielectric layers 944. Each horizontal trench can extend in a horizontal direction, and can be used as a space for a gate structure 939 to be formed in the subsequent processes. It is noted that, the term “horizontal/horizontally” used herein means nominally parallel to a lateral surface of first substrate 910.

In some implementations, stack sacrificial layers 942 include silicon nitride, and the etchant of the isotropic dry etch includes one or more of CF₄, CHF₃, C4F₈, C4F₆, and CH₂F₂. The radio frequency (RF) power of the isotropic dry etch can be lower than about 100 W, and the bias can be lower than about 10 V. In some implementations, stack sacrificial layers 942 include silicon nitride, and the etchant of the wet etch includes phosphoric acid. After stack sacrificial layers 942 are removed, the multiple slits 960 and multiple horizontal trenches can be cleaned by using any suitable cleaning process. For example, a phosphoric acid rinsing process can be performed to remove the impurities on the inner wall of the horizontal trenches. In some implementations, a rinsing temperature can be in a range from about 100° C. to about 200° C., and a rinsing time can be in a range from about 10 minutes to about 100 minutes.

In some implementations, stack gate structures 939 can be formed in horizontal trenches, as shown in FIG. 9C. In some implementations, each stack gate structure 939 can include a gate electrode 935 (also referred to as stack conductive layer 935) wrapped by insulating film 933 and high-k dielectric layer 931. The insulating film 933 and high-k dielectric layer 931 can be used as one or more gate dielectric layers for insulating the respective word line (i.e., gate electrode 935). In some implementations, insulating film 933 and high-k dielectric layer 931 can be formed to cover the exposed surfaces of the horizontal trenches with one or more suitable insulating materials. For example, one or more suitable deposition processes, such as CVD, PVD, and/or ALD, can be utilized to deposit the one or more insulating materials into the horizontal trenches. In some implementations, a recess etching process and/or a CMP process can be used to remove excessive insulating material(s). The one or more insulating materials can include any suitable materials that provide an electrical insulating function. In some implementations as shown in FIG. 9C, high-k dielectric layer 931 is formed along the sidewall and at the bottom of slit 960, and on the top surface of filling insulating structure 947 as well.

In some implementations, gate electrodes 935 can be formed in horizontal trenches respectively. Gate electrodes 935 can be formed by filling the horizontal trenches with a suitable gate electrode metal material. Gate electrodes 935 can provide the base material for the word lines. The gate electrode metal material can include any suitable conductive material, e.g., tungsten, aluminum, copper, cobalt, or any combination thereof, for forming the word lines. The gate electrode material can be deposited into horizontal trenches using a suitable deposition method such as CVD, PVD, plasma-enhanced CVD (PECVD), sputtering, metal-organic chemical vapor deposition (MOCVD), and/or ALD.

In some implementations as shown in FIG. 9C, portions of stack gate structures 939 (e.g., portions of insulating film 933 and gate electrodes 935 exposed by slit 960) can be removed by a recess etching process. In some implementations, in order to ensure the insulation between multiple gate electrodes 935, a recess etching process, such as a wet etching process, can be performed to remove the exposed portions of the multiple gate structures 939. In doing so, a recess can be formed in each horizontal trench adjacent to the sidewalls of slit 960. Memory stack 930 including interleaved stack gate structures 939 and stack dielectric layers 944 is thereby formed, replacing dielectric stack structure 940 (shown in FIG. 9C), according to some implementations.

Referring back to FIG. 8, method 800 can then proceed to operation 807, in which a gate line slit structure can be formed in each slit.

In some implementations as shown in FIG. 9D, portions of high-k dielectric layer 931 on the top surface of filling insulating structure 947 can be removed by using a dry etching process. The remaining portions of high-k dielectric layer 931 on the sidewalls and the bottom of slit 960 can be kept and used as a stop layer in the subsequent processes. A first gate line spacer (GLSP) layer 963 and a second GLSP layer 965 can then be formed on both sidewalls and on the bottom surface of each slit 960. In some implementations, first GLSP layer 963 can be formed by using any suitable deposition process, such as an atomic layer deposition (ALD) process to deposit a low temperature oxide material, and second GLSP layer 965 can be formed by using any suitable deposition process, such as an atomic layer deposition (ALD) process to deposit a high temperature oxide material. In some implementations, as shown in FIG. 9D, filling structure 968 can be a conductive wall formed in each slit 960 by performing a deposition process to fill each slit 960 with any suitable conductive material, such as metal materials including tungsten, aluminum, copper, polysilicon, silicides, and/or combinations thereof, etc. The first and second GLSP layers 963 and 965 can be used to provide electrical insulation between the multiple gate structures 939 and filling structure 968. A CMP process can be performed to planarize the top surfaces of the one or more filling structures 968. Filling structure 968 and first and second GLSP layers 963, 965 can form gate line slit structure 969.

Referring back to FIG. 8, method 800 can then proceed to operation 809, in which a plurality of channel structure contacts, word line contacts, and a plurality of first interconnect contacts can be formed. As such, the first semiconductor structure 920 is formed, as shown in cross-sectional views in both X-Z plane and Y-Z plane in FIG. 9D.

In some implementations, a plurality of channel structure contacts 981 and word line contacts 983 can be formed to connect with the respective array wafer structure. For example, the lower end of each channel structure contacts 981 can be in contact with corresponding semiconductor channel 957 in channel structure 950, the lower end of each word line contacts 983 can be in contact with corresponding gate electrode 935 (word line) in one level of staircase structure 949. It is understood that, a fabricating process for forming the plurality of channel structure contacts 981 and word line contacts 983 can include multiple processes, for example, photolithography, etching, thin film deposition, and CMP. For example, the plurality of channel structure contacts 981 and word line contacts 983 can be formed through the filling insulating structure 947 by first deep etching vertical openings (e.g., by wet etching and/or dry etching), followed by filling the vertical openings with conductor materials using ALD, CVD, PVD, any other suitable processes, or any combination thereof. The conductor materials used for filling the vertical openings can include, but are not limited to, W, Co, Cu, Al, polysilicon, silicides, or any combination thereof. In some implementations, other conductor materials are also used to fill the openings to function as a barrier layer, an adhesion layer, and/or a seed layer.

In some implementations, the plurality of channel structure contacts 981, word line contacts 983, and/or one or more ACS contacts, can be simultaneously formed in the same contact forming process. In some implementations, each process in the contact forming process needs to be performed only once for all of the channel structure contacts 981, word line contacts 983, and/or ACS contacts. For example, a single lithography process can be performed to pattern the masks for all the openings of channel structure contacts 981, word line contacts 983, and/or ACS contacts; a single etching process can be performed to etch all the openings of channel structure contacts 981, word line contacts 983, and/or ACS contacts; a single deposition process can be performed to fill all the openings of channel structure contacts 981, word line contacts 983, and/or ACS contacts with the same conductor materials.

As shown in FIG. 9D, a plurality of first interconnect contacts 989 can be formed in filling insulating structure 947. The upper end of each first interconnect contact 989 can be flush with one another at the top surface of filling insulating structure 947, and the lower end of each first interconnect contact 989 can be flush with one another at the bottom surface of the filling insulating structure 947, and can be in contact with the upper end of a corresponding channel structure contact 981, word line contact 983, or ACS contact.

A plurality of first interconnect contacts 989 can be formed through filling insulating structure 947 by first etching vertical openings (e.g., by wet etching and/or dry etching), followed by filling the openings with conductor materials using ALD, CVD, PVD, any other suitable processes, or any combination thereof. The conductor materials used to form first interconnect contacts 989 can include, but are not limited to, W, Co, Cu, Al, polysilicon, silicides, or any combination thereof. In some implementations, other conductor materials are used to fill the openings to function as a barrier layer, an adhesion layer, and/or a seed layer. In some implementations, each first interconnect contact 989 can include multiple sub-contacts formed in the multiple sub-layers. For example, the multiple sub-contacts can include one or more contacts, single-layer/multi-layer vias, conductive lines, plugs, pads, and/or any other suitable filling structures that are made by conductive materials including, but not limited to, W, Co, Cu, Al, doped silicon, silicides, or any combination thereof, and can be formed in multiple contact forming processes. For example, fabrication processes to form the multiple sub-contacts can include forming one or more conductive layers and one or more contact layers in the corresponding sub-layers of filling insulating structure 947. The conductive layers and the conductor contact layers can be formed by any suitable known back-end-of-line (BEOL) methods. In some implementations, all first interconnect contacts 989 can be simultaneously formed in the same contact forming processes. In some implementations, first interconnect contacts 989 can be used for connecting channel structure contacts 981, word line contacts 983, and/or ACS contacts.

Referring back to FIG. 8, method 800 proceeds to operation 811, in which a second semiconductor structure, including a periphery circuit and a plurality of second interconnect contacts on a second substrate, can be bonded to the first semiconductor structure.

In some implementations, as shown in FIG. 9E, second semiconductor structure 990 can include a periphery circuit 993 and a plurality of second interconnect contacts 999 located on a second substrate 991. In some implementations, second substrate 991 can be any suitable semiconductor substrate having any suitable structure, such as a monocrystalline single-layer substrate, a polycrystalline silicon (p oly sili con) single-layer substrate, a polysilicon and metal multi-layer substrate, etc.

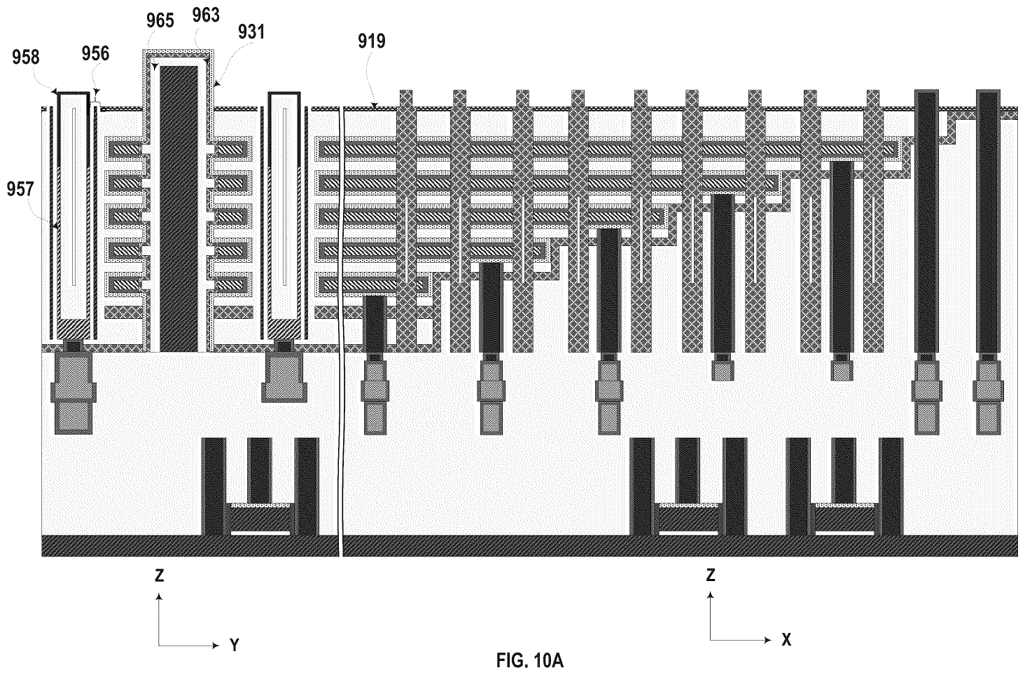

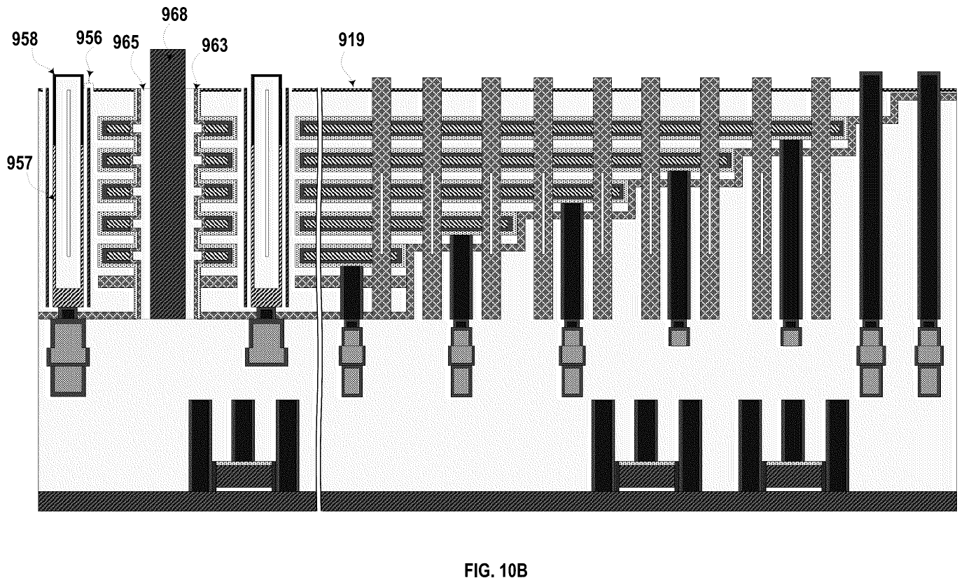

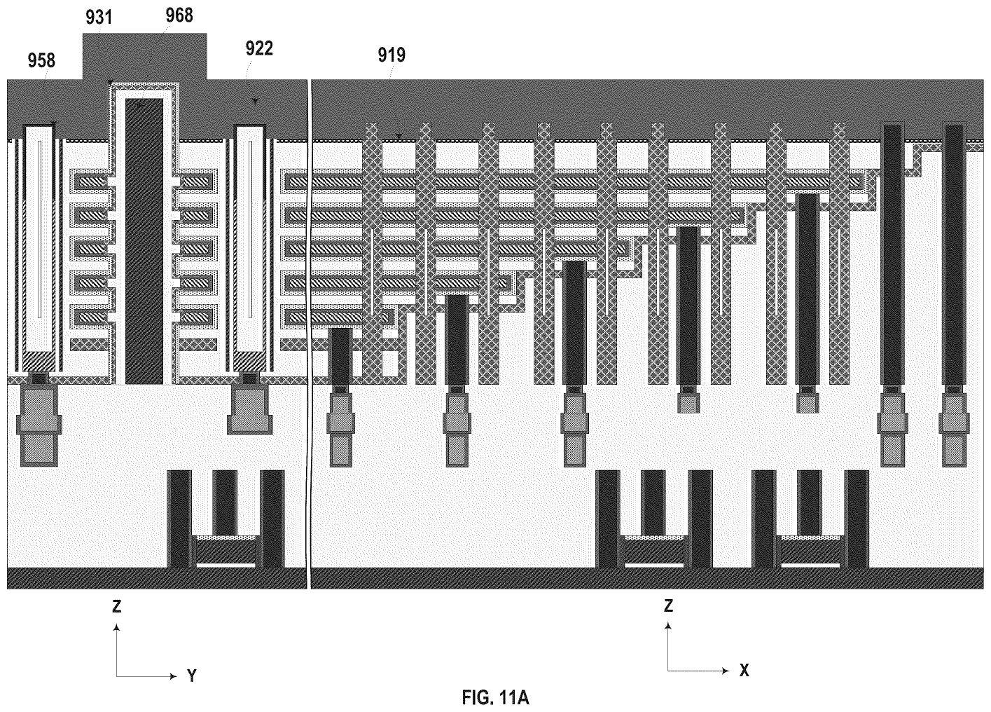

In some implementations, as illustrated in FIG. 9E, periphery circuit 993 can be formed on second substrate 991 using a plurality of processes including, but not limited to, photolithography, etching, thin film deposition, thermal growth, implantation, chemical mechanical polishing (CMP), and any other suitable processes. In some implementations, periphery circuit 993 includes a plurality of transistors 995 that are separated from each other by STIs (not shown) formed by wet etching and/or dry etching and thin film deposition. In some implementations, doped regions (e.g., wells, sources, and drains of transistors 995, not shown) can be formed on or in second substrate 991 by ion implantation and/or thermal diffusion, which function, for example, as source regions and/or drain regions of transistors 995. Corresponding transistor contacts (e.g., gate contact, source contact, and drain contact) can be formed in an insulating layer 997 covering second substrate 991. In some implementations, insulating layer 997 can include any suitable insulating material and/or dielectric material, such as silicon oxide, etc. In some implementations as shown in FIG. 10A, insulating layer 997 can be an oxide layer deposited on second substrate 991 and covering periphery circuit 993.

A plurality of second interconnect contacts 999 can be formed in insulating layer 997 by first etching vertical openings (e.g., by wet etching and/or dry etching), followed by filling the openings with conductor materials using ALD, CVD, PVD, any other suitable processes, or any combination thereof. The conductor materials used to form second interconnect contacts 999 can include, but are not limited to, W, Co, Cu, Al, polysilicon, silicides, or any combination thereof. In some implementations, other conductor materials are used to fill the openings to function as a barrier layer, an adhesion layer, and/or a seed layer. In some implementations, each second interconnect contact 999 can include multiple sub-contacts formed in the multiple sub-layers. For example, the multiple sub-contacts can include one or more contacts, single-layer/multi-layer vias, conductive lines, plugs, pads, and/or any other suitable filling structures that are made by conductive materials including, but not limited to, W, Co, Cu, Al, doped silicon, silicides, or any combination thereof, and can be formed in multiple contact forming processes. For example, fabrication processes to form the multiple sub-contacts can include forming one or more conductive layers and one or more contact layers in the corresponding sub-layers of insulating layer 997. The conductive layers and the conductor contact layers can be formed by any suitable known back-end-of-line (BEOL) methods. In some implementations, all second interconnect contacts 999 can be simultaneously formed in the same contact forming processes. In some implementations, second interconnect contacts 999 can be used for connecting transistors 995.

As shown in FIG. 9E, the first semiconductor structure 920 and the second semiconductor structure 990 can be bonded in a face-to-face manner. That is, the second semiconductor structure 990 (i.e., second substrate 991 and components formed thereon, such as periphery circuit 993 and second interconnect contacts 999) are flipped upside down, and bonded to the first semiconductor structure 920. The bonding can include hybrid bonding. As such, first semiconductor structure 920 and second semiconductor structure 990 can be bonded together in a face-to-face manner at bonding interface 925, according to some implementations. In some implementations, a treatment process, e.g., a plasma treatment, a wet treatment, and/or a thermal treatment, is applied to the bonding surfaces of first semiconductor structure 920 and second semiconductor structure 990 prior to the bonding. After the bonding, corresponding first inter interconnect contacts 989 and second interconnect contacts 999 are aligned and in contact with one another, such that memory stack 930 and channel structures 950 can be electrically connected to periphery circuit 993.

Referring back to FIG. 8, method 800 proceeds to operation 813, in which part of the first substrate and part of the channel structure are sequentially removed to expose part of the semiconductor channels of the channel structures. The removal can be performed from the backside of the second substrate. The upper portions of the semiconductor channel of each channel structure can be doped, and a supplemental semiconductor layer can be formed to electrically connect with the doped semiconductor channel region of each channel structure.

As shown in FIG. 9F, in some implementations, the bonded 3D structure can be flipped upside down, such that first semiconductor structure 920 is located above second semiconductor structure 990 to expose the backside of first substrate 910. In some implementations, sacrificial substrate 911 can be removed from the backside until being stopped by first stop layer 913. Sacrificial substrate 911 can be removed using dry etching, and/or wet etching. In some implementations, sacrificial substrate 911 can be removed using wet etching by tetramethylammonium hydroxide (TMAH), which is automatically stopped when reaching first stop layer 913 having materials other than silicon, i.e., acting as a backside etch stop layer. In some implementations, in the region corresponding to the gate line slit structure 969, the etching can stop at high-k dielectric layer 931.

As shown in FIG. 9G, in some implementations, after removing sacrificial substrate 911, first stop layer 913 and initial semiconductor layer 915 can be sequentially removed. In some implementations, first stop layer 913 can be removed using wet etching with suitable etchants, such as phosphoric acid and hydrofluoric acid, until being stopped by initial semiconductor layer 915 having a different material (e.g., silicon) from the material of first stop layer 913. Next, initial semiconductor layer 915 can be removed by a selective wet etching, and stopping at second stop layer 917. As such, portions of channel structure 950 extended above second stop layer 917 can be exposed.

After that, second stop layer 917 and portions of functional layer 956 of each channel structure 950 extended above barrier layer 919 can be removed, as shown in FIGS. 10A and 10B. For example, a selective wet etching process can be performed to simultaneously remove second stop layer 917, and the portions of blocking layer 951, storage layer 953, and tunneling layer 955 that extend above barrier layer 919. The etching process can be controlled by controlling the etching time and/or etching rate, such that the etching does not continue beyond barrier layer 919 into memory stack 930. As such, an upper portion of semiconductor channel 957 of each channel structure 950 can be exposed. In some implementations as shown in FIG. 10A, high-k dielectric layer 931, first and second GLSP layers 963, 965 of gate line slit structure 969 are not removed during the selective wet etching process. In some other implementations as shown in FIG. 10B, when high-k dielectric layer 931 includes oxide aluminum, portions of high-k dielectric layer 931, and portions of first and second GLSP layers 963, 965 of gate line slit structure 969 that are extended above barrier layer 919 can be also removed during the selective wet etching process to expose filling structure 968.

As shown in FIGS. 10A and 10B, in some implementations, the top portion of semiconductor channel 957 can be doped to increase its conductivity to form a doped semiconductor channel region 958. For example, a tilted ion implantation (IMP) process may be performed to dope the top portion of semiconductor channel 957 (e.g., including polysilicon) with p-type dopants (e.g., boron, indium, gallium, etc.), or n-type dopants (e.g., phosphorus, arsenic, etc.), to a desired doping concentration. For p-type in-situ doping, p-type doping precursors, such as, but not limited to, diborane (B₂H₆) and boron trifluoride (BF₃), can be used. For n-type in-situ doping, n-type doping precursors, such as, but not limited to, PH₃ and AsH₃, can be used. In some implementations, after the IMP process, an array thermal treatment can be applied to the top surface of the formed 3D structure to active dopants in doped semiconductor channel region 958.

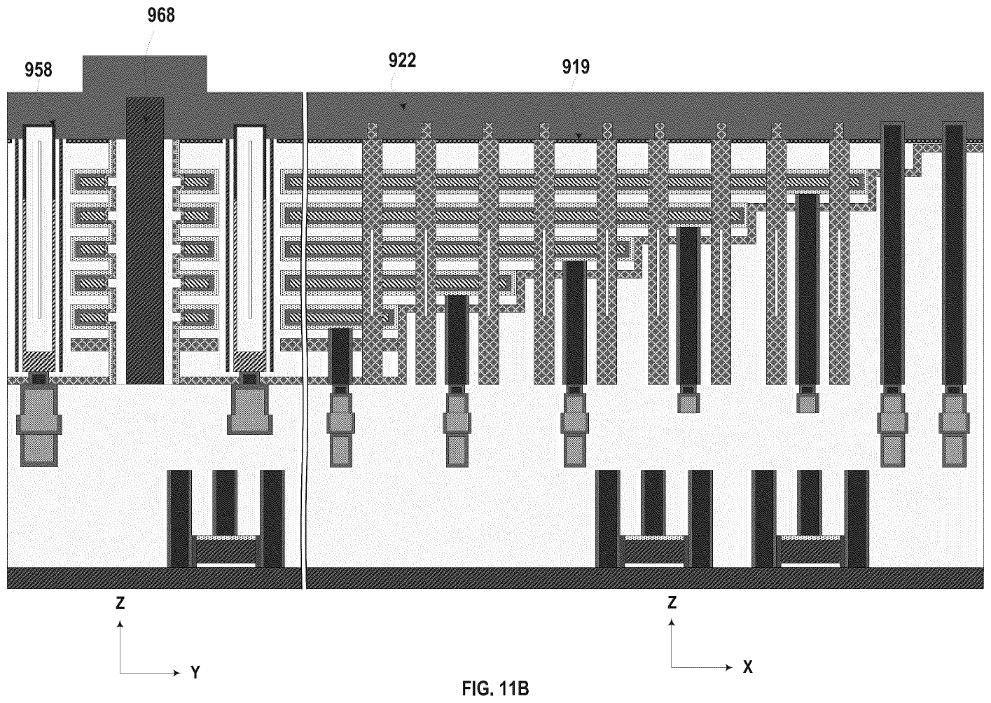

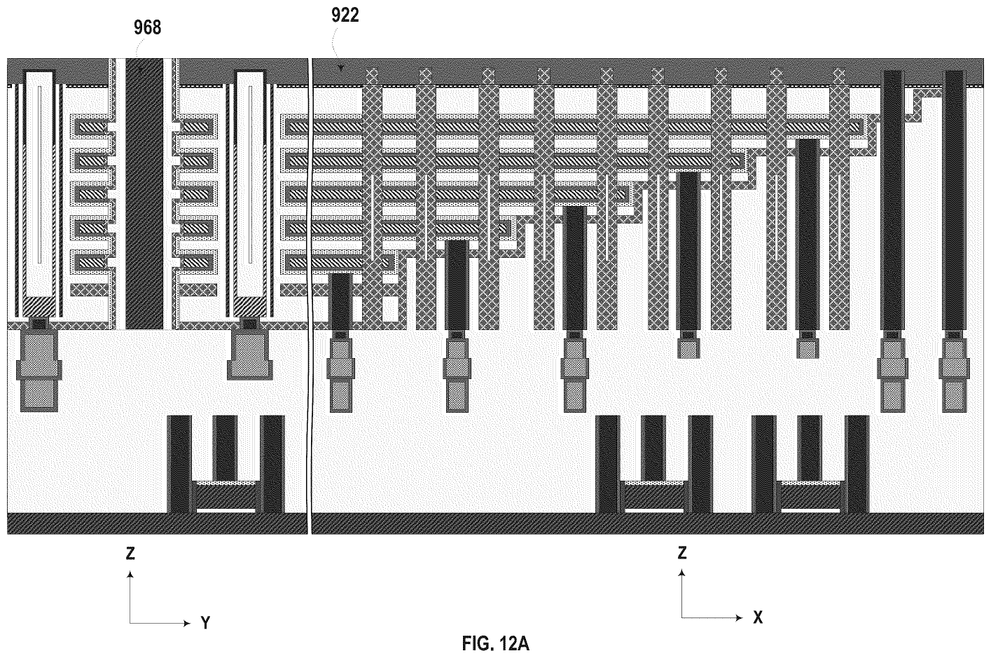

As shown in FIGS. 11A and 11B, supplemental semiconductor layer 922 can be formed to cover barrier layer 919. Supplemental semiconductor layer 922 can be in electrical contact with the doped semiconductor channel region 958 of each channel structure 950. In some implementations as shown in FIG. 11A, when portions of high-k dielectric layer 931 and portions of first and second GLSP layers 963, 965 of gate line slit structure 969 extended above barrier layer 919 are not removed in previous process (referring to FIG. 10A), supplemental semiconductor layer 922 is not in contact with filling structure 968. In some other implementations as shown in FIG. 11B, when portions of high-k dielectric layer 931 and portions of first and second GLSP layers 963, 965 of gate line slit structure 969 extended above barrier layer 919 are removed in the previous process (referring to FIG. 10B), supplemental semiconductor layer 922 can be in direct contact with filling structure 968.

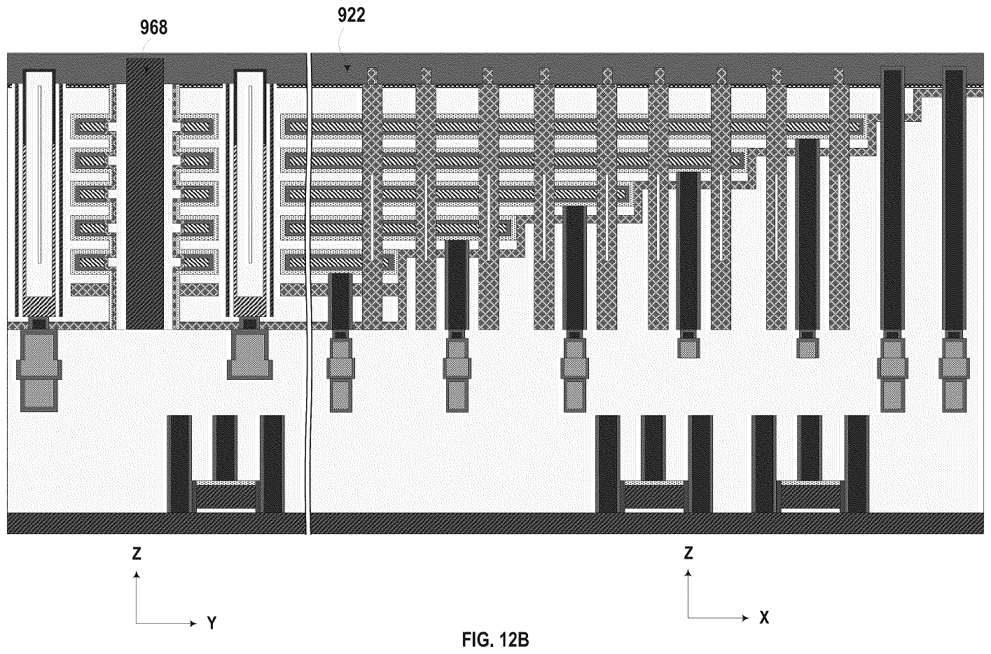

In some implementations, fabricating processes of supplemental semiconductor layer 922 can further include a chemical mechanical polishing (CMP) process to planarize the top surfaces of supplemental semiconductor layer 922 as shown in FIGS. 12A and 12B. It is noted that, in some implementations as shown in FIG. 12A, the CMP process can remove the upper portions of the supplemental semiconductor layer 922 as well as upper portions of the high-k dielectric layer 931 and upper portions of first and second GLSP layers 963, 965 of gate line slit structure 969 simultaneously, such that supplemental semiconductor layer 922 does not in contact with filling structure 968. In some other implementations as shown in FIG. 12B, since the upper portions of the high-k dielectric layer 931 and the upper portions of first and second GLSP layers 963, 965 extend beyond barrier layer 919 were removed in previous processes, supplemental semiconductor layer 922 is in direct contact with filling structure 968 after the CMP process.

In some implementations, one or more local activation processes can be performed on certain portions (e.g., the core region) of supplemental semiconductor layer 922 to activate the supplemental semiconductor layer. In some implementations, during the one or more local activation processes, amorphous silicon material of the supplemental semiconductor layer can be converted to polycrystalline silicon material. It is noted that, the one or more local activation processes can be performed in one or more predetermined regions of supplemental semiconductor layer 922 to locally activate the amorphous silicon material. In some implementations, the activation process may include a local thermal treatment, such as a laser anneal process. In some implementations, the temperature of the local thermal treatment may range from 1300 degrees Celsius to 1700 degrees Celsius. In some implementations, the laser anneal process includes a plurality of laser pulses in a laser beam, each having a pulse time of 100 ns (i.e., nanoseconds) to 300 ns.

Referring back to FIG. 8, method 800 proceeds to operation 815, in which a pad layer can be formed on the supplemental semiconductor to electrically connect with the supplemental semiconductor layer.

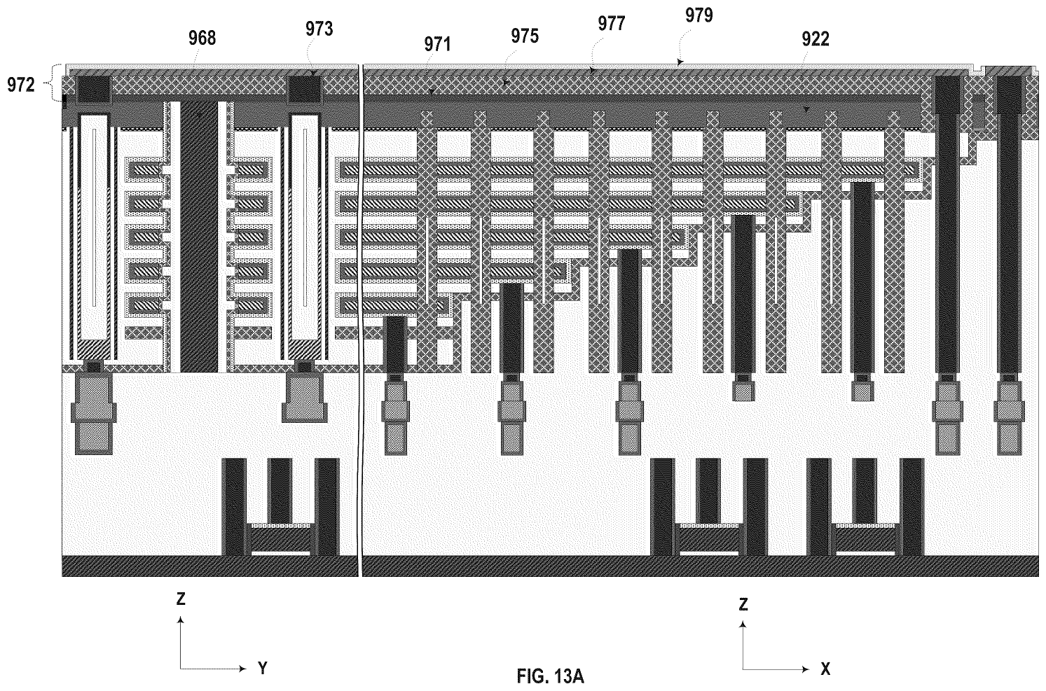

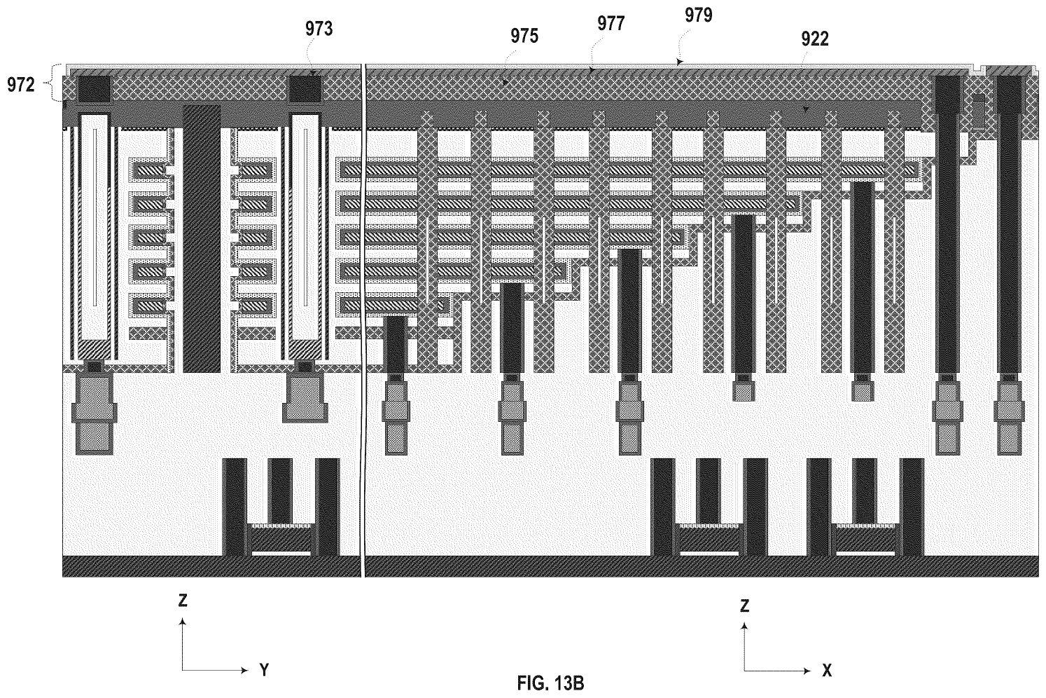

In some implementations as shown in FIG. 13A, pad layer 972 can include a connecting layer 971 in contact with supplemental semiconductor layer 922 and filling structure 968, multiple pad structures 973 embedded in a pad dielectric layer 975 and in contact with connecting layer 971. In some implementations, connecting layer 971 can include any suitable conductive materials including, but not limited to, W, Co, Cu, Al, doped silicon, silicides, or any combination thereof, and can be used to electrically connect supplemental semiconductor layer 922, filling structure 968, and pad structures 973. In some other implementations as shown in FIG. 13B, since supplemental semiconductor layer 922 is in direct contact with filling structure 968, the connecting layer can be omitted, and multiple pad structures 973 embedded in pad dielectric layer 975 can be in direct contact with supplemental semiconductor layer 922. As shown in FIGS. 13A and 13B, in some implementations, pad layer 972 can further include wiring layer 977 on pad structures 973 and pad dielectric layer 975. In some implementations, pad layer 972 can further include protection layer 979 on wiring layer 977 and pad dielectric layer 975.

Pad dielectric layer 975 can include one or more layers of dielectric materials such as silicon oxide, silicon nitride, silicon oxynitride, or any combination thereof, and can be formed by one or more thin film deposition processes, such as ALD, CVD, PVD, any other suitable processes, or any combination thereof. In some implementations as shown in FIG. 13A, pad dielectric layer 975 can be formed to cover connecting layer 971. In some implementations as shown in FIG. 13B, pad dielectric layer 975 can be formed to cover supplemental semiconductor layer 922.

Each pad structure 973 can be formed in pad dielectric layer 975, and include one or more contacts, single-layer/multi-layer vias, conductive lines, plugs, pads, and/or any other suitable filling structures that are made by conductive materials including, but not limited to, W, Co, Cu, Al, doped silicon, silicides, or any combination thereof. The upper end of each pad structure 973 can be flush with one another at the top surface of pad dielectric layer 975, and the lower end of each pad structure 973 can be in contact with corresponding contacts, and in contact with connecting layer 971 as shown in FIG. 13A, or in contact with supplemental semiconductor layer 922 as shown in FIG. 13B.

It is understood that, a contact process for forming the multiple pad structures 973 can include multiple processes, for example, photolithography, etching, thin film deposition, and CMP. In some implementations, a hard mask layer can be formed on the pad dielectric layer 975, and multiple vertical through openings can be formed in the pad dielectric layer 975 by a wet etching and/or dry etching by using the hard mask layer. A followed deposition process can form the multiple pad structures 973 by filling the multiple vertical through openings with conductor materials using ALD, CVD, PVD, any other suitable processes, or any combination thereof. The conductor materials used for filling the multiple vertical through openings can include, but are not limited to, W, Co, Cu, Al, polysilicon, silicides, or any combination thereof.

Wiring layer 977 can be a patterned conductive layer formed on pad structures 973 and pad dielectric layer 975, as shown in FIGS. 13A and 13B. In some implementations, fabricating processes of forming wiring layer 977 can include forming a conductive layer over pad structures 973 and pad dielectric layer 975. After that, a resist mask is formed by a photolithography process, and unnecessary portions can be removed by etching to form wirings. In some implementations, the resist mask used for forming the wiring layer 977 can be formed with an ink-jet method. Wiring layer 977 can be formed with a single-layer structure or a layered structure using any of metal materials such as molybdenum (Mo), titanium (Ti), chromium (Cr), tantalum (Ta), tungsten (W), aluminum (Al), copper (Cu), neodymium (Nd), scandium (Sc), etc., and an alloy material including any of these materials as a main component.

In some implementations, protection layer 979 can be formed to cover wiring layer 977 and/or pad dielectric layer 975. Protection layer 979 can include an insulating sublayer and a polymer sublayer. The insulating sublayer can be a nitride layer, such as a metal nitride layer. The polymer sublayer can be any suitable nanoconfinement of polymers configured to prevent scratching of or damage to wiring layer 977.

It is noted that, any suitable processes can be performed during or after any operations of method 800 described above. For example, when barrier layer 919 is a polysilicon layer or a metal layer, an oxidation process can be performed during operation 805, after forming slits 960 and before forming high-k dielectric layer 931, to oxidize portions of barrier layer 919 exposed by slits 960. As such, an oxide structure 499 can be formed between barrier layer 919 and high-k dielectric layer 931, as shown in FIGS. 4B and 5B, to avoid potential damages to low temperature oxide material of first GLSP layer 965 during back side etching processes of operation 813.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A method for forming a three-dimensional (3D) memory device, comprising:
forming a first semiconductor structure, comprising:
forming a stack structure on a first substrate, and
forming a gate line slit structure including a filling structure penetrating the stack structure and extending into the first substrate;
forming a second semiconductor structure including a periphery circuit on a second substrate;
bonding the second semiconductor structure to the first semiconductor structure;
removing a portion of the first substrate and a portion of the gate line slit structure extended into the first substrate; and
forming a supplemental semiconductor layer on a remaining portion of the first substrate.

2. The method of claim 1, wherein forming the first semiconductor structure further comprises:
forming the first substrate including a sacrificial substrate, a first stop layer, an initial semiconductor layer, a second stop layer, and a barrier layer stacked in a vertical direction;
forming a dielectric stack structure including a plurality of dielectric layer pairs stacked on the first substrate, each dielectric layer pair including a sacrificial layer and a dielectric layer different from the sacrificial layer; and
forming a plurality of channel structures penetrating the dielectric stack structure, each channel structure including a functional layer and a semiconductor channel.

3. The method of claim 2, wherein forming the first semiconductor structure further comprises:
forming a slit penetrating the dielectric stack structure and extending into the first substrate;
removing the plurality of stack sacrificial layers in the dielectric stack structure through the slit to form a plurality of horizontal trenches;
forming a high-k dielectric layer to cover exposed surfaces of the plurality of horizontal trenches and on sidewalls and on a bottom of the slit; and
forming a gate structure in each horizontal trench.

4. The method of claim 3, wherein forming the gate line slit structure comprises:
forming at least one gate line spacer layer on the high-k dielectric layer; and
forming the filling structure to fill the slit.

5. The method of claim 4, further comprising:
before forming the high-k dielectric layer, performing an oxidization process to oxidize a portion of the barrier layer exposed by the slit.

6. The method of claim 4, wherein removing the portion of the first substrate and the portion of the gate line slit structure comprises:
removing the sacrificial substrate and stopping at the first stop layer;
removing the first stop layer and the initial semiconductor layer and stopping at the second stop layer to expose portions of the channel structures and portions of the high-k dielectric layer of the gate line slit structure;
removing a portion of the functional layer of each channel structure to expose the semiconductor channel; and
doping a portion of the semiconductor channel of each channel structure.

7. The method of claim 6, wherein removing the portion of the functional layer of each channel structure comprises:
removing portions of a blocking layer, a storage layer, and a tunneling layer of each channel structure that extend beyond the barrier layer; and
simultaneously removing the second stop layer.

8. The method of claim 7, further comprising:
removing portions of the high-k dielectric layer and portions of the at least one gate line spacer layer that extend beyond the barrier layer to expose a portion of the filling structure extended beyond the barrier layer.

9. The method of claim 7, wherein forming the supplemental semiconductor layer comprises:
forming the supplemental semiconductor layer on the barrier layer to electrically connect with the doped portion of the semiconductor channel of each channel structure;
performing a local thermal to active the supplemental semiconductor layer; and
performing a chemical mechanical polishing process to planarize a top surface of the supplemental semiconductor layer.

10. The method of claim 9, further comprising:
forming a connecting layer on the supplemental semiconductor layer to electrically connect between portions of the supplemental semiconductor layer that are separated by the gate line slit structure.

11. The method of claim 1, further comprising forming a pad layer on the supplemental semiconductor layer, comprising:
forming a pad dielectric layer on the supplemental semiconductor layer;
forming a plurality of pad structures embedded in the pad dielectric layer;
forming a wiring layer on the pad dielectric layer to connect with the plurality of pad structures; and
forming a protection layer to cover the wiring layer.

12. The method of claim 1, wherein bonding the second semiconductor structure to the first semiconductor structure comprises:
hybrid bonding the second semiconductor structure to the first semiconductor structure in a face-to-face manner.

13. A three-dimensional (3D) memory device, comprising:
a first semiconductor structure comprising:
a stack structure comprising alternately arranged gate structures and dielectric layers on a semiconductor layer, and
a gate line slit structure extending through the stack structure, comprising a filling structure sandwiched by gate line spacer layers; and
a second semiconductor structure comprising a periphery circuit;
wherein the second semiconductor structure coupled to the first semiconductor structure.

14. The device of claim 13, wherein the first semiconductor structure further comprises:
a connecting layer on the semiconductor layer to electrically connect portions of the semiconductor layer that are separated by the gate line slit structure.

15. The device of claim 13, wherein the filling structure is extended into and in direct contact with the semiconductor layer.

16. The device of claim 13, wherein the first semiconductor structure further comprises:
a barrier layer between the stack structure and the semiconductor layer;
a plurality of channel structures extending through the stack structure and the barrier layer, each channel structure including a functional layer and a semiconductor channel;
a staircase structure in the stack structure; and
a plurality of dummy channel structures penetrating the staircase structure.

17. The device of claim 16, wherein:
the functional layer of each channel structure comprises a blocking layer, a storage layer, and a tunneling layer; and
the semiconductor channel comprises:
an undoped semiconductor channel region in contact with a corresponding channel structure contact, and
a doped semiconductor channel region penetrating the barrier layer and in contact with the semiconductor layer.

18. The device of claim 17, further comprising a pad layer on the semiconductor layer, the pad layer comprising:
a dielectric layer on semiconductor layer;
a plurality of pad structures embedded in the pad dielectric layer;
a wiring layer attached to the pad dielectric layer to connect with the plurality of pad structures; and
a protection layer covering the wiring layer.

19. The device of claim 13, wherein the first semiconductor structure further comprises:
a high-k dielectric layer located between adjacent dielectric layer and gate structure along a lateral direction, and between the stack structure and the gate line slit structure along a vertical direction.

20. A memory system, comprising:
a memory device configured to store data, and comprising:
a first semiconductor structure comprising:
a stack structure comprising an array of memory cells, and
a gate line slit structure extending through the stack structure, comprising a filling structure sandwiched by gate line spacer layers; and
a second semiconductor structure comprising a periphery circuit, wherein the second semiconductor structure coupled to the first semiconductor structure; and
a memory controller coupled to the memory device and configured to control the array of memory cells through the periphery circuit.
